(19) United States
(12) Patent Application Publication
(10) Pub. No.: US 2024/0047245 A1
(43) Pub. Date: Feb. 8, 2024

(54) SUBSTRATE TREATMENT METHOD AND SUBSTRATE TREATMENT DEVICE

(71) Applicant: SCREEN Holdings Co., Ltd., Kyoto (JP)

(72) Inventors: Kana TAHARA, Kyoto (JP); Yukifumi YOSHIDA, Kyoto (JP)

(21) Appl. No.: 18/550,751

(22) PCT Filed: Jan. 11, 2022
(86) PCT No.: PCT/JP2022/000589

§ 371 Date: Sep. 15, 2023

(30) Foreign Application Priority Data
Mar. 19, 2021 (JP) 2021-046460

(51) Int. Cl. H01L 21/67; H01L 21/311

(52) U.S. Cl. CPC H01L 21/6715; H01L 21/6708; H01L 21/67051; H01L 21/31133

(57) ABSTRACT

A substrate processing method etches a substrate. The substrate processing method includes an oxide layer forming step of oxidizing a surface layer portion of a major surface of the substrate and forming an oxide layer and an oxide layer removing step of forming a polymer film that contains an acid polymer on the major surface of the substrate and removing the oxide layer by the acid polymer contained in the polymer film. The oxide layer forming step and the oxide layer removing step are alternately repeated.

### TECHNICAL FIELD

The present invention relates to a substrate processing method for processing a substrate and a substrate processing apparatus that processes a substrate.

Examples of substrates to be processed include semiconductor wafers, substrates for FPDs (Flat Panel Displays) such as liquid crystal displays or organic EL (Electroluminescence) displays, substrates for optical disks, substrates for magnetic disks, substrates for magneto-optical disks, substrates for photomasks, ceramic substrates, substrates for solar batteries, etc.

### BACKGROUND ART

United States Patent Application Publication No. 2020/303207 discloses substrate processing in which a desired amount of etching is achieved by repeatedly performing a step of supplying an oxidation fluid, such as hydrogen peroxide water (H₂O₂ water), to a substrate and forming a metal oxide layer and a step of supplying an etching liquid, such as diluted hydrofluoric acid (DHF), to the substrate and removing the metal oxide layer.

### CITATION LIST

### Patent Literature

Patent Literature 1: United States Patent Application Publication No. 2020/303207

### SUMMARY OF INVENTION

### Technical Problem

In the substrate processing of United States Patent Application Publication No. 2020/303207, the metal oxide layer is etched by repeatedly performing the formation of the metal oxide layer and the removal of the metal oxide layer, and therefore the metal oxide layer is enabled to be more accurately etched than in a case in which a large amount of metal oxide layers is removed at a time.

However, in the substrate processing of United States Patent Application Publication No. 2020/303207, a process is employed in which the formation and the removal of the metal oxide layer are performed by continuously-flowing diluted hydrofluoric acid and hydrogen peroxide water, respectively. Therefore, in the substrate processing, a large amount of chemical liquid, such as diluted hydrofluoric acid or hydrogen peroxide water, is required to be used, and therefore the problem of an environmental load arises.

Therefore, an object of the present invention is to provide a substrate processing method and a substrate processing apparatus that are capable of accurately etching a substrate and that are capable of making a substance for use in the etching of the substrate small in amount used.

### Solution to Problem

A preferred embodiment of the present invention provides a substrate processing method that etches a substrate. The substrate processing method includes an oxide layer forming step of oxidizing a surface layer portion of a major surface of the substrate and forming an oxide layer and an oxide layer removing step of forming a polymer film that contains an acid polymer on the major surface of the substrate and removing the oxide layer by the acid polymer contained in the polymer film. The oxide layer forming step and the oxide layer removing step are alternately repeated.

According to this substrate processing method, the formation and the removal of the oxide layer are alternately repeated. Therefore, it is possible to accurately etch the substrate. Additionally, according to this substrate processing method, the oxide layer is removed by the acid polymer contained in the polymer film formed on the major surface of the substrate. The polymer film contains the acid polymer, and hence is semisolid or solid. Therefore, the polymer film stays on the major surface of the substrate more easily than a liquid. Therefore, there is no need to continuously supply an acid polymer to the major surface of the substrate during the entire period of time during which the oxide layer is removed. In other words, there is no need to supplementarily supply an acid polymer to the major surface of the substrate at least after forming the polymer film. Therefore, it is possible to make the acid polymer, which is a substance for use in the etching of the substrate, small in amount used.

As a result, it is possible to make a substance used to etch the substrate small in amount used while accurately etching the substrate.

In a preferred embodiment of the present invention, the polymer film additionally contains an alkaline component. The oxide layer removing step includes a removal starting step of starting removal of the oxide layer by heating the polymer film and then evaporating the alkali component from the polymer film after the polymer film is formed.

With this configuration, the alkaline component is contained in the polymer film together with the acid polymer. Therefore, the acid polymer is neutralized by the alkaline component, and is in a substantially deactivated state until the polymer film is heated after the polymer film is formed. Therefore, the removal of the oxide layer is not started until the polymer film is heated after the polymer film is formed. The acid polymer contained in the polymer film regains activity by heating the polymer film and by evaporating the alkaline component, and the removal of the oxide layer is started. Therefore, it is possible to accurately etch the substrate. Particularly, it is possible to accurately control the starting timing of the etching of the substrate.

In a preferred embodiment of the present invention, the polymer film additionally contains an electroconductive polymer. Therefore, it is possible to facilitate ionization of the acid polymer contained in the polymer film by the action of the electroconductive polymer. Therefore, it is possible to allow the acid polymer to effectively act on the oxide layer.

In other words, the electroconductive polymer functions as a medium for allowing the acid polymer to release protons (hydrogen ions) in the same way as the solvent. Therefore, if the electroconductive polymer is contained in the polymer film, it is possible to ionize the acid polymer and is possible to allow the acid polymer that has been ionized to act on the oxide layer even if the solvent has been completely eliminated from the polymer film.

In a preferred embodiment of the present invention, the substrate processing method further includes a polymer-film removing step of removing the polymer film from the major surface of the substrate after the oxide layer removing step is completed and before the oxide layer forming step subsequent to the oxide layer removing step is started.

According to this substrate processing method, the formation of the subsequent oxide layer is started after the polymer film is removed from the substrate, thereby making it possible to prevent the oxide layer from being removed while oxidizing the surface layer portion of the major surface of the substrate. In detail, it is possible to prevent the oxide layer formed in the oxide layer forming step from being removed by an acid polymer remaining on the major surface of the substrate, thereby making it possible to prevent the formation and the removal of the oxide layer from occurring in a chain-reaction manner in the oxide layer forming step. Therefore, it is possible to prevent the amount of the surface layer portion of the major surface of the substrate etched (removed) from becoming larger than envisioned. In other words, the substrate is enabled to be etched more highly accurately.

In a preferred embodiment of the present invention, the oxide layer forming step includes a wet oxidation step of forming the oxide layer by supplying a liquid oxidant to the major surface of the substrate. Therefore, it is possible to oxidize the substrate through a simple step of supplying the liquid oxidant to the substrate.

In a preferred embodiment of the present invention, the substrate processing method further includes a rinsing step of supplying a rinsing liquid that washes the major surface of the substrate to the major surface of the substrate after the oxide layer forming step and before the oxide layer removing step.

According to this substrate processing method, the liquid oxidant is washed away from the major surface of the substrate by means of the rinsing liquid. In other words, the removal of the oxide layer is started after the liquid oxidant is removed from the substrate, thereby making it possible to prevent the oxide layer from being formed while removing the oxide layer. In detail, it is possible to prevent the oxide layer from being further formed by the oxidant remaining on the major surface of the substrate while the oxide layer is being removed by the acid polymer contained in the polymer film, thereby making it possible to prevent the formation and the removal of the oxide layer from occurring in a chain-reaction manner in the oxide layer removing step. Therefore, it is possible to prevent the amount of the substrate etched from becoming larger than envisioned. In other words, the substrate is enabled to be etched more highly accurately.

In a preferred embodiment of the present invention, the substrate processing method further includes a substrate holding step of allowing a spin chuck to hold the substrate. The oxide layer forming step includes a heating oxidation step of forming the oxide layer by heating the substrate held by the spin chuck, and the oxide layer removing step includes a step of forming the polymer film on the major surface of the substrate held by the spin chuck.

According to this substrate processing method, it is possible to oxidize the surface layer portion of the major surface of the substrate without using an oxidant. Therefore, it is possible to make a substance for use in etching the substrate small in amount used. Additionally, the formation and the removal of the oxide layer are performed in a state in which the substrate is being held by the same spin chuck. Therefore, there is no need to move the substrate, and therefore it is possible to more swiftly remove the oxide layer than a configuration in which the formation and the removal of the oxide layer are respectively performed in a state in which the substrate is being held by mutually different spin chucks.

Additionally, it is possible to facilitate the removal of the oxide layer by using the amount of heat given to the substrate, which has been heated to form the oxide layer, for heating the polymer film. Consequently, it is possible to reduce a period of time required for substrate processing.

In a preferred embodiment of the present invention, the heating oxidation step includes a step of forming the oxide layer by heating the substrate by means of a heater unit. The substrate processing method further includes a polymer-film heating step of heating the polymer film through the substrate by means of the heater unit while performing the oxide layer removing step.

According to this substrate processing method, it is possible to also use the heater unit, which is used for the formation of the oxide layer, for heating the polymer film. Therefore, there is no need to provide a heater unit differing from the heater unit used for heating by which the substrate is oxidized, and therefore it is possible to simplify substrate processing.

Additionally, the heater unit that is used for heating by which the oxide layer is formed is also used for heating the polymer film, and, as a result, it is possible to use the amount of heat, which has been stored in the heater unit for the formation of the oxide layer, for heating the polymer film.

For example, if an alkaline component is contained in the polymer film, it is possible to facilitate the removal of the alkaline component, and it is possible to facilitate the action of removing an oxide layer by means of an acid polymer contained in the polymer film regardless of the presence or absence of the alkaline component. Therefore, it is possible to more efficiently facilitate the etching of the substrate than a configuration in which a heater unit differing from the heater unit used to form the oxide layer is provided to heat the polymer film.

In a preferred embodiment of the present invention, the oxide layer forming step includes a dry oxidation step of forming the oxide layer by at least any one among light irradiation, heating, and supply of a gaseous oxidant.

According to this substrate processing method, it is possible to form an oxide layer without using a liquid oxidant. Therefore, it is possible to save labor hours for removing a liquid oxidant adhering to the major surface of the substrate. Particularly, if a configuration is formed to oxidize the major surface of the substrate by means of light irradiation and heating or by means of a combination of light irradiation and heating, it is possible to make a substance required to etch the substrate small in amount used.

In a preferred embodiment of the present invention, the substrate processing method further includes a polymer-containing liquid supplying step of supplying a polymer-containing liquid that contains at least a solvent and the acid polymer to the major surface of the substrate. In this substrate processing method, the oxide layer removing step includes a polymer-film forming step of forming the polymer film by evaporating at least a portion of the solvent contained in the polymer-containing liquid on the major surface of the substrate.

According to this substrate processing method, it is possible to form a polymer film by evaporating the solvent from the polymer-containing liquid supplied to the substrate. Therefore, it is possible to raise the concentration of the acid polymer contained in the polymer film by evaporating the solvent. Therefore, it is possible to swiftly etch the substrate by means of the high-concentrated acid polymer.

In a preferred embodiment of the present invention, the substrate processing method further includes a mixed liquid supplying step of supplying a mixed liquid that contains at least a solvent, the acid polymer, and an oxidant to the major surface of the substrate. In this substrate processing method, the oxide layer removing step includes a polymer-film forming step of forming the polymer film by evaporating at least a portion of the solvent contained in the mixed liquid on the major surface of the substrate. In this substrate processing method, the oxide layer forming step includes a mixed liquid oxidation step of forming the oxide layer by means of the oxidant contained in the mixed liquid supplied to the major surface of the substrate.

According to this substrate processing method, the surface layer portion of the major surface of the substrate is oxidized by the oxidant contained in the mixed liquid. Thereafter, the oxide layer is removed by the acid polymer contained in the polymer film formed by evaporating the solvent contained in the mixed liquid on the major surface of the substrate. In other words, the mixed liquid is supplied to the major surface of the substrate, and the polymer film is formed from the mixed liquid on the major surface of the substrate, and, as a result, the formation and the removal of the oxide layer are successively performed. Therefore, it is possible to make a substance for use in the etching of the substrate smaller in amount used than in a case in which a continuously-flowing liquid is used for each of the formation and the removal of the oxide layer.

In a preferred embodiment of the present invention, the mixed liquid supplying step includes a nozzle supplying step of discharging a mixed liquid from a mixed liquid nozzle and supplying the mixed liquid discharged from the mixed liquid nozzle to the substrate. The substrate processing method further includes a mixed liquid forming step of forming a mixed liquid by mixing a liquid oxidant and an acid polymer liquid that contains an acid polymer together in a pipe connected to the mixed liquid nozzle.

According to this substrate processing method, a liquid oxidant and an acid polymer liquid are mixed together in the pipe connected to the mixed liquid nozzle, and, as a result, a mixed liquid is formed. Therefore, the mixed liquid is formed immediately before the oxidant and the acid polymer are supplied to the major surface of the substrate. Therefore, even if the oxidant and the acid polymer chemically react with each other, it is possible to make a substance for use in the etching of the substrate small in amount used while restraining a chemical change in both the oxidant and the acid polymer.

In a preferred embodiment of the present invention, the mixed liquid supplying step includes a nozzle supplying step of discharging a mixed liquid from a mixed liquid nozzle and supplying the mixed liquid discharged from the mixed liquid nozzle to the substrate. The substrate processing method further includes a mixed liquid forming step of forming a mixed liquid by mixing a liquid oxidant and an acid polymer liquid together in a mixed liquid tank that supplies a mixed liquid to a pipe that guides a mixed liquid to the mixed liquid nozzle.

According to this substrate processing method, the liquid oxidant and the acid polymer liquid are mixed together in the mixed liquid tank, and, as a result, a mixed liquid is formed. Therefore, it is possible to make a substance for use in the etching of the substrate smaller in amount used while simplifying its equipment than in a configuration in which the liquid oxidant and the acid polymer liquid are supplied from mutually-different tanks to the mixed liquid nozzle.

Another preferred embodiment of the present invention provides a substrate processing apparatus that etches a substrate. The substrate processing apparatus includes a substrate oxidizing unit that oxidizes a surface layer portion of a major surface of the substrate, a polymer-film forming unit that forms a polymer film containing an acid polymer on the major surface of the substrate, and a controller that controls the substrate oxidizing unit and the polymer-film forming unit so that oxidization of the surface layer portion of the major surface of the substrate by means of the substrate oxidizing unit and formation of the polymer film by means of the polymer-film forming unit are alternately repeated.

With this substrate processing apparatus, the same effect as the above-described substrate processing method is fulfilled.

The above and other objects, features, and advantages of the present invention will become more apparent from the following detailed description of the preferred embodiments with reference to the attached drawings.

### BRIEF DESCRIPTION OF DRAWINGS

FIG. 1 is a schematic cross-sectional view for describing a structure of a surface layer portion of a substrate to be processed.

FIG. 2A is a plan view for describing a configuration of a substrate processing apparatus according to a first preferred embodiment of the present invention.

FIG. 2B is an elevational view for describing the configuration of the substrate processing apparatus.

FIG. 3 is a schematic cross-sectional view for describing a configuration example of a wet processing unit included in the substrate processing apparatus.

FIG. 4 is a block diagram for describing a configuration example concerning the control of the substrate processing apparatus.

FIG. 5 is a flowchart for describing an example of substrate processing performed by the substrate processing apparatus.

FIG. 6A is a schematic view for describing an aspect of a substrate when the substrate processing is performed.

FIG. 6B is a schematic view for describing an aspect of the substrate when the substrate processing is performed.

FIG. 6C is a schematic view for describing an aspect of the substrate when the substrate processing is performed.

FIG. 6D is a schematic view for describing an aspect of the substrate when the substrate processing is performed.

FIG. 6E is a schematic view for describing an aspect of the substrate when the substrate processing is performed.

FIG. 6F is a schematic view for describing an aspect of the substrate when the substrate processing is performed.

FIG. 6G is a schematic view for describing an aspect of the substrate when the substrate processing is performed.

FIG. 7 is a schematic view for describing a change in a surface layer portion of an upper surface of the substrate caused by allowing an oxide layer forming step and an oxide layer removing step to be alternately repeated in the substrate processing.

FIG. 8 is a schematic view for describing a structure of the surface layer portion of the substrate when a polymer film is formed.

FIG. 9A is a schematic view for describing an aspect in which an oxide layer in a grain boundary is etched by an etching liquid composed of a low-molecular-weight etching component.

FIG. 9B is a schematic view for describing an aspect in which an oxide layer in a grain boundary is etched by a polymer film.

FIG. 10 is a flowchart for describing another example of substrate processing performed by the substrate processing apparatus.

FIG. 11 is a schematic view for describing an aspect of a substrate when another example of the substrate processing is performed.

FIG. 12 is a schematic view for describing a first example of a method of supplying a polymer-containing liquid to a substrate in the substrate processing apparatus.

FIG. 13 is a schematic view for describing a second example of a method of supplying a polymer-containing liquid to a substrate in the substrate processing apparatus.

FIG. 14 is a schematic view for describing a first modification of the wet processing unit.

FIG. 15 is a schematic view for describing a second modification of the wet processing unit.

FIG. 16 is a schematic view for describing a third modification of the wet processing unit.

FIG. 17 is a plan view for describing a configuration of a substrate processing apparatus according to a second preferred embodiment.

FIG. 18 is a schematic cross-sectional view for describing a configuration example of a light irradiation treatment unit included in the substrate processing apparatus according to the second preferred embodiment.

FIG. 19 is a flowchart for describing an example of substrate processing performed by the substrate processing apparatus according to the second preferred embodiment.

FIG. 20 is a schematic cross-sectional view for describing a heat treatment unit included in the substrate processing apparatus according to the second preferred embodiment.

FIG. 21 is a flowchart for describing another example of substrate processing performed by the substrate processing apparatus according to the second preferred embodiment.

FIG. 22 is a schematic cross-sectional view for describing a configuration example of a wet processing unit included in a substrate processing apparatus according to a third preferred embodiment.

FIG. 23 is a flowchart for describing an example of substrate processing performed by the substrate processing apparatus according to the third preferred embodiment.

FIG. 24A is a schematic view for describing an aspect of a substrate when an example of the substrate processing according to the third preferred embodiment is performed.

FIG. 24B is a schematic view for describing an aspect of the substrate when an example of the substrate processing according to the third preferred embodiment is performed.

FIG. 24C is a schematic view for describing an aspect of the substrate when an example of the substrate processing according to the third preferred embodiment is performed.

FIG. 24D is a schematic view for describing an aspect of the substrate when an example of the substrate processing according to the third preferred embodiment is performed.

FIG. 25 is a schematic view for describing a first example of a method of supplying a mixed liquid to a substrate.

FIG. 26 is a schematic view for describing a second example of a method of supplying a mixed liquid to a substrate.

### DESCRIPTION OF EMBODIMENTS

<Structure of Surface Layer Portion of Substrate to be Processed>

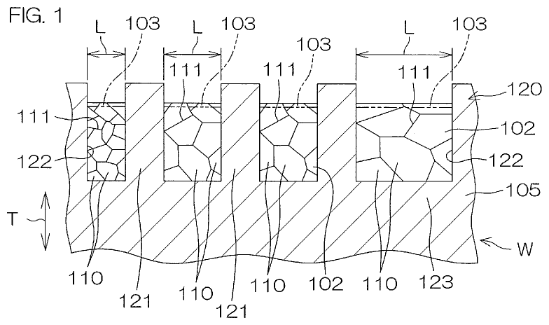

FIG. 1 is a schematic cross-sectional view for describing a structure of a surface layer portion of a substrate W to be processed. The substrate W is a substrate such as a silicon wafer, and has a pair of major surfaces. At least one of the pair of major surfaces is a device surface on which a concavo-convex pattern 120 is formed. One of the pair of major surfaces may be a non-device surface on which a device is not formed.

For example, an insulation layer 105 in which a plurality of trenches 122 are formed and a to-be-processed layer 102 formed in each of the trenches 122 so as to expose its front surface are formed at the surface layer portion of the device surface. The insulation layer 105 has a fine convex structure 121 placed between the trenches 122 adjoining each other and a bottom defining portion 123 that defines a bottom portion of the trench 122. The concavo-convex pattern 120 includes of the plurality of structures 121 and the plurality of trenches 122. A front surface of the to-be-processed layer 102 and a front surface of the insulation layer 105 (structure 121) compose at least a portion of the major surface of the substrate W.

For example, the insulation layer 105 is a silicon oxide (SiO₂) layer or a low-permittivity layer. The low-permittivity layer is made of low-permittivity (Low-k) material that is lower in permittivity than silicon oxide. In detail, the low-permittivity layer is made of insulation material (SiOC) in which carbon is added to silicon oxide.

For example, the to-be-processed layer 102 is a metal layer, a silicon layer, or the like, and, typically, is a copper wiring. The metal layer is formed by crystal growth through an electroplating technique or the like while using a seed layer (not shown) formed in the trench 122 as a nucleus by, for example, a sputtering method. The metal-layer forming method is not limited to this method. The metal layer may be formed only by sputtering, or may be formed by another method.

The to-be-processed layer 102 is oxidized, and, as a result, an oxide layer 103 is formed (see the alternate long and two short dashed line of FIG. 1). The oxide layer 103 is, for example, a metal oxide layer, and, typically, is a copper oxide layer.

A barrier layer and a liner layer may be provided between the to-be-processed layer 102 and the insulation layer 105 in the trench 122. The barrier layer is, for example, tantalum nitride (TaN), and the liner layer is, for example, ruthenium (Ru) or cobalt (Co).

The trench 122 is, for example, linear. The width L of the linear trench 122 is a magnitude of the trench 122 in a direction in which the trench 122 extends and in a direction perpendicular to a thickness direction T of the substrate W. All of the widths L of the plurality of trenches 122 are not necessarily the same, and trenches 122 respectively having at least two kinds of widths L are formed near a surface layer of the substrate W. The width L is a width of the to-be-processed layer 102 and a width of the oxide layer 103.

The width L of the trench 122 is, for example, not less than 20 nm and not more than 500 nm. The depth D of the trench 122 is a magnitude of the trench 122 in the thickness direction T, and is, for example, 200 nm or less.

The to-be-processed layer 102 is formed by crystal growth through an electroplating technique or the like while using a seed layer (not shown) formed in the trench 122 as a nucleus by, for example, a sputtering method.

The to-be-processed layer 102 and the oxide layer 103 are made of a plurality of crystal grains 110. An interface between the crystal grains 110 is referred to as a grain boundary 111. The grain boundary 111 is a kind of lattice defect, and is formed by disorder in atomic arrangement.

The crystal grain 110 becomes slower in growth in proportion to narrowness of the width L of the trench 122, and becomes faster in growth in proportion to wideness of the width L of the trench 122. Therefore, it is possible to more easily make a small crystal grain 110 in proportion to narrowness of the width L of the trench 122, and it is possible to more easily make a large crystal grain 110 in proportion to wideness of the width L of the trench 122. In other words, the grain boundary density becomes higher in proportion to a decrease in the width L of the trench 122, and the grain boundary density becomes lower in proportion to an increase in the width L of the trench 122.

<Configuration of Substrate Processing Apparatus According to First Preferred Embodiment>

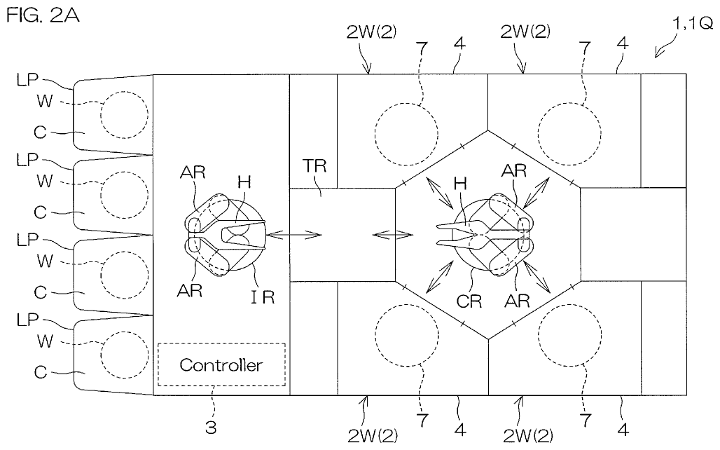

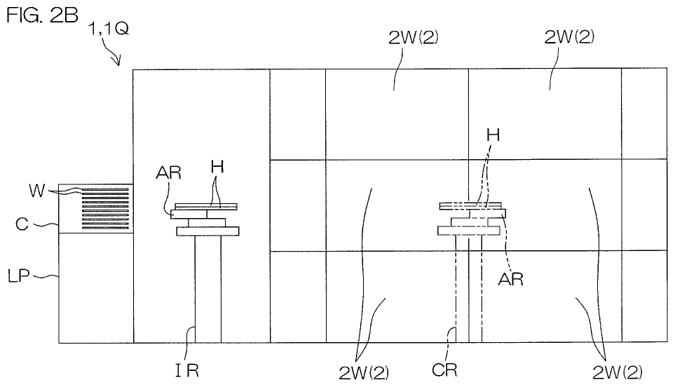

FIG. 2A is a plan view for describing a configuration of the substrate processing apparatus 1 according to a first preferred embodiment of the present invention. FIG. 2B is an elevational view for describing a configuration of the substrate processing apparatus 1.

The substrate processing apparatus 1 is a single substrate processing type apparatus that processes substrates W one by one. The substrate W is a disk-shaped substrate in the preferred embodiment. The substrate W is processed in an attitude in which a device surface is directed upwardly in the preferred embodiment.

The substrate processing apparatus 1 includes a plurality of processing units 2 that process a substrate W, a load port LP on which a carrier C housing a plurality of substrates W that are processed by the processing unit 2 is placed, transfer robots IR and CR each of which transfers a substrate W between the load port LP and the processing unit 2, and a controller 3 that controls the substrate processing apparatus 1.

The transfer robot IR transfers a substrate W between the carrier C and the transfer robot CR. The transfer robot CR transfers a substrate W between the transfer robot IR and the processing unit 2.

Each of the transfer robots IR and CR is, for example, an articulated-arm robot including a pair of articulated arms AR and a pair of hands H respectively provided at front ends of the pair of articulated arms AR so as to recede from each other upwardly and downwardly.

The plurality of processing units 2 respectively form four processing towers disposed at four positions distant horizontally. Each of the processing towers includes the plurality of processing units 2 stacked together in the up-down direction (in the preferred embodiment, three processing units) (see FIG. 2B). The four processing towers are disposed two by two on both sides of a transfer path TR that extends from the load port LP toward the transfer robots IR, CR (see FIG. 2A).

In the first preferred embodiment, the processing unit 2 is a wet processing unit 2W that processes a substrate W with a liquid. Each of the wet processing units 2W includes a chamber 4 and a processing cup 7 disposed in the chamber 4, and performs a processing operation for a substrate W in the processing cup 7.

The chamber 4 has an entrance/exit (not shown) through which a substrate W is carried in or is carried out by the transfer robot CR. The chamber 4 is provided with a shutter unit (not shown) that opens and closes this entrance/exit.

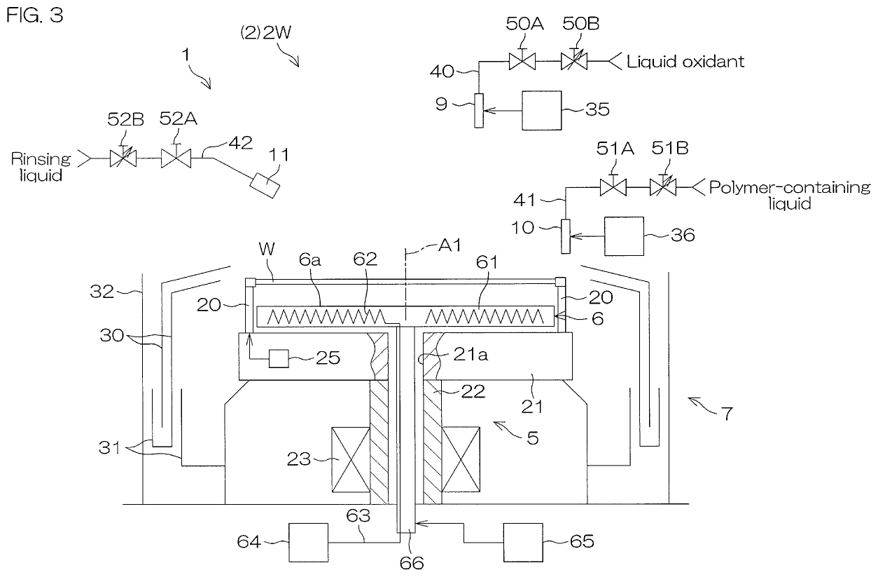

FIG. 3 is a schematic cross-sectional view for describing a configuration example of the wet processing unit 2W.

The wet processing unit 2W additionally includes a spin chuck 5 that rotates a substrate W around a rotational axis A1 (vertical axis) while holding the substrate W at a predetermined first holding position and a heater unit 6 that heats the substrate W held by the spin chuck 5. The rotational axis A1 is a vertical straight line that passes through a central portion of the substrate W. The first holding position is a position of the substrate W shown in FIG. 3, and is a position at which the substrate W is held in a horizontal attitude.

The spin chuck 5 includes a spin base 21 that has a disk shape along a horizontal direction, a plurality of chuck pins 20 that grip a substrate W above the spin base 21 and that hold the substrate W at the first holding position, a rotational shaft 22 an upper end of which is connected to the spin base 21 and that extends in the vertical direction, and a spin motor 23 that rotates the rotational shaft 22 around its central axis (rotational axis A1).

The plurality of chuck pins 20 are disposed at a distance from each other in a circumferential direction of the spin base 21 on an upper surface of the spin base 21. The spin motor 23 is an electric motor. The spin motor 23 rotates the rotational shaft 22, and, as a result, allows the spin base 21 and the plurality of chuck pins 20 to rotate around the rotational axis A1. Thereby, the substrate W is rotated around the rotational axis A1 together with the spin base 21 and the plurality of chuck pins 20.

The plurality of chuck pins 20 are movable between a closed position at which the chuck pins 20 grip the substrate W while being in contact with a peripheral edge portion of the substrate W and an open position to which the chuck pins 20 recede from the peripheral edge portion of the substrate W. The plurality of chuck pins 20 are moved by an opening-closing unit 25. The plurality of chuck pins 20 horizontally hold (clamp) the substrate W when the chuck pins 20 are placed at the closed position. When placed at the open position, the plurality of chuck pins 20 release the grip of the peripheral edge portion of the substrate W while coming into contact with a peripheral edge portion of a lower surface (major surface on the lower side) of the substrate W and supporting the substrate W from below.

The opening-closing unit 25 includes, for example, a link mechanism that moves the plurality of chuck pins 20 and a driving source that gives a driving force to the link mechanism. The driving source includes, for example, an electric motor.

The heater unit 6 is an example of a substrate heating unit that heats the entirety of the substrate W. The heater unit 6 has a form of a disk-shaped hot plate. The heater unit 6 is disposed between the upper surface of the spin base 21 and the lower surface of the substrate W. The heater unit 6 has a heating surface 6a that faces the lower surface of the substrate W from below.

The heater unit 6 includes a plate main body 61 and a heater 62. The plate main body 61 is slightly smaller than the substrate W in a plan view. An upper surface of the plate main body 61 forms the heating surface 6a. The heater 62 may be a resistive element built into the plate main body 61. The heating surface 6a is heated by energizing the heater 62. The heater 62 can heat the substrate W to a temperature substantially equal to the temperature of the heater 62. The heater 62 is configured to be able to heat the substrate W within a temperature range of not less than a normal temperature (for example, not less than 5° C. and not more than 25° C.) and not more than 400° C.

An elevation shaft 66 that is inserted in a through-hole 21a formed in a central portion of the spin base 21 and that is inserted in a hollow rotational shaft 22 is connected to a lower surface of the heater unit 6. An energizing unit 64 is connected to the heater 62 through an electric supply line 63, and an electric current supplied from the energizing unit 64 is adjusted, and, as a result, the temperature of the heater 62 is changed to a temperature within the above-described temperature range.

The heater unit 6 is raised and lowered by a heater elevation driving mechanism 65. The heater elevation driving mechanism 65 includes an electric motor or an actuator (not shown), such as an air cylinder, that drives and raises or lowers the elevation shaft 66. The heater elevation driving mechanism 65 raises and lowers the heater unit 6 through the elevation shaft 66. The heater unit 6 can be raised and lowered between the lower surface of the substrate W and the upper surface of the spin base 21.

When rising, the heater unit 6 is capable of receiving the substrate W from the plurality of chuck pins 20 placed at the open position. The heater unit 6 is capable of heating the substrate W by being placed at a contact position at which the heating surface 6a comes into contact with the lower surface of the substrate W or at a proximal position at which the heating surface 6a approaches the lower surface of the substrate W in a non-contact state. A position to which the heater unit 6 sufficiently recedes from the lower surface of the substrate W to such a degree that the heater unit 6 stops heating the substrate W is referred to as a retreat position.

The processing cup 7 receives a liquid scattering from the substrate W held by the spin chuck 5. The processing cup 7 includes a plurality of (in the example of FIG. 3, two) guards 30 that catch a liquid that scatters outwardly from the substrate W held by the spin chuck 5, a plurality of (in the example of FIG. 3, two) cups 31 that catch a liquid that is downwardly guided by the plurality of guards 30, and a circular-cylindrical outer-wall member 32 that surrounds the plurality of guards 30 and the plurality of cups 31. The plurality of guards 30 are individually raised and lowered by a guard elevation driving mechanism (not shown). The guard elevation driving mechanism places the guard 30 at an arbitrary position from the upper position to the lower position.

The processing unit 2 additionally includes an oxidant nozzle 9 that supplies a liquid oxidant, such as hydrogen peroxide water, to the upper surface (upper major surface) of the substrate W held by the spin chuck 5, a polymer-containing liquid nozzle 10 that supplies a polymer-containing liquid that contains an acid polymer, an alkaline component, and an electroconductive polymer to the upper surface of the substrate W held by the spin chuck 5, and a rinsing-liquid nozzle 11 that supplies a rinsing liquid, such as DIW (Deionized Water), to the upper surface of the substrate W held by the spin chuck 5.

The liquid oxidant is a liquid that oxidizes the surface layer portion of the to-be-processed layer exposed from the upper surface of the substrate W and that forms an oxide layer at the surface layer portion of the to-be-processed layer. The oxide layer formed by the liquid oxidant has a thickness of, for example, not less than 1 nm and not more than 2 nm.

The liquid oxidant is, for example, hydrogen peroxide water (H₂O₂ water) that contains hydrogen peroxide (H₂O₂) as an oxidant or ozonized water (O₃ water) that contains ozone (O₃) as an oxidant.

The oxidant is not necessarily required to be hydrogen peroxide or ozone. The oxidant is merely required to be an oxidant that can oxidize the to-be-processed layer exposed from the upper surface of the substrate W. For example, a plurality of oxidants may be contained in the liquid oxidant, and, in detail, the liquid oxidant may be a liquid formed by dissolving both hydrogen peroxide and ozone into DIW. The oxidant nozzle 9 is an example of a substrate oxidation unit.

The oxidant nozzle 9 is a movable nozzle that is movable at least in the horizontal direction. The oxidant nozzle 9 is moved in the horizontal direction by means of a first nozzle moving unit 35. The first nozzle moving unit 35 includes an arm (not shown) that is united with the oxidant nozzle 9 and that extends horizontally and an arm moving unit (not shown) that moves the arm in the horizontal direction. The arm moving unit may have an electric motor or an air cylinder, or may have an actuator other than these devices. A nozzle moving unit described later has the same configuration.

The oxidant nozzle 9 may be movable in the vertical direction. The oxidant nozzle 9 is capable of approaching the upper surface of the substrate W or receding upwardly from the upper surface of the substrate W by moving in the vertical direction. Unlike the preferred embodiment, the oxidant nozzle 9 may be a stationary nozzle whose horizontal and vertical positions are fixed.

The oxidant nozzle 9 is connected to an end of an oxidant pipe 40 that guides a liquid oxidant to the oxidant nozzle 9. The other end of the oxidant pipe 40 is connected to an oxidant tank (not shown). An oxidant valve 50A that opens and closes a flow path in the oxidant pipe 40 and an oxidant flow-rate adjusting valve 50B that adjusts the flow rate of a liquid oxidant in this flow path are interposed in the oxidant pipe 40.

When the oxidant valve 50A is opened, a liquid oxidant is discharged downwardly from a discharge port of the oxidant nozzle 9 in a continuous flow at a flow rate according to the opening degree of the oxidant flow-rate adjusting valve 50B.

The polymer-containing liquid contains a solute and a solvent that dissolves the solute. The solute of the polymer-containing liquid includes an acid polymer, an alkaline component, and an electroconductive polymer.

The acid polymer is an acid polymer that dissolves an oxide layer without oxidizing a to-be-processed layer. The acid polymer is solid at a normal temperature, and releases protons into the solvent, and exhibits acidity.

The molecular weight of the acid polymer is, for example, not less than 1000 and not more than 100000. The acid polymer is not limited to polyacrylic acid. The acid polymer is, for example, a carboxyl-containing polymer, a sulfo-containing polymer, or a mixture of these polymers. The carboxylic polymer is, for example, polyacrylic acid, carboxy vinyl polymer (carbomer), carboxymethylcellulose, or a mixture of these substances. The sulfo-containing polymer is, for example, polystyrene sulfonic acid, polyvinyl sulfonic acid, or a mixture of these substances.

It is desirable for a solvent contained in the polymer-containing liquid to be a liquid at a normal temperature, to be capable of dissolving or swelling an acid polymer, and to be evaporated by rotating or heating the substrate W. The solvent contained in the polymer-containing liquid is not limited to DIW, and is, preferably, a water-based solvent. The solvent contains at least one among DIW, carbonic water, electrolyzed ion water, hydrochloric acid water having a diluted concentration (for example, not less than 1 ppm and not more than 100 ppm), ammonia water having a diluted concentration (for example, not less than 1 ppm and not more than 100 ppm), and restoration water (hydrogenated water).

The alkaline component is, for example, ammonia. The alkaline component is not limited to ammonia. In detail, the alkaline component includes, for example, ammonia, tetramethylammonium hydroxide (TMAH), dimethylamine, or a mixture of these substances. Preferably, the alkaline component is a component that is evaporated by being heated at temperature less than the boiling point of the solvent and that exhibits alkalinity in the solvent. Particularly preferably, the alkaline component is ammonia, which is a gas at a normal temperature, or is dimethylamine and a mixture of these substances.

The electroconductive polymer is not limited to polyacetylene. The electroconductive polymer is a conjugated polymer having a conjugated double bond. The conjugated polymer is, for example, an aliphatic conjugated polymer such as polyacetylene, an aromatic conjugated polymer such as poly (p-phenylene), a mixed conjugated polymer such as poly (p-phenylene vinylene), a heterocyclic conjugated polymer such as polypyrrole, polythiophene, and poly (3, 4-ethylene dioxythiophene) (PEDOT), a heteroatom-containing conjugated polymer such as polyaniline, a plural-chain conjugated polymer such as polyacene, a two-dimensional conjugated polymer such as graphene, or a mixture of these substances.

The polymer-containing liquid nozzle 10 is a movable nozzle that is movable at least in the horizontal direction. The polymer-containing liquid nozzle 10 is moved in the horizontal direction by means of a second nozzle moving unit 36 that has the same configuration as the first nozzle moving unit 35. The polymer-containing liquid nozzle 10 may be movable in the vertical direction. Unlike the preferred embodiment, the polymer-containing liquid nozzle 10 may be a stationary nozzle whose horizontal and vertical positions are fixed.

The polymer-containing liquid nozzle 10 is connected to an end of a polymer-containing liquid pipe 41 that guides a polymer-containing liquid to the polymer-containing liquid nozzle 10. The other end of the polymer-containing liquid pipe 41 is connected to a polymer-containing liquid tank (not shown). A polymer-containing liquid valve 51A that opens and closes a flow path in the polymer-containing liquid pipe 41 and a polymer-containing liquid flow-rate adjusting valve 51B that adjusts the flow rate of a polymer-containing liquid in this flow path are interposed in the polymer-containing liquid pipe 41.

When the polymer-containing liquid valve 51A is opened, a polymer-containing liquid is discharged downwardly from a discharge port of the polymer-containing liquid nozzle 10 in a continuous flow at a flow rate according to the opening degree of the polymer-containing liquid flow-rate adjusting valve 51B.

At least a portion of the solvent is evaporated from a polymer-containing liquid supplied to the upper surface of the substrate W, and, as a result, the polymer-containing liquid on the substrate W changes into a semisolid or solid polymer film. The term “semisolid” denotes a state in which a solid constituent and a liquid constituent are mixed together or a state in which the film is enabled to have such a viscosity as to keep a predetermined shape on the substrate W. The term “solid” denotes a state in which the film does not contain a liquid constituent, and is made of only a solid constituent. The polymer film in which the solvent remains is semisolid, and the polymer film in which the solvent has been completely eliminated is solid.

An alkaline component and an electroconductive polymer, in addition to an acid polymer, are contained in the polymer-containing liquid as a solute. Therefore, an acid polymer, an alkaline component, and an electroconductive polymer are contained in the polymer film.

The polymer film is neutral in a state in which an alkaline component and an acid polymer are contained in the polymer film. In other words, the acid polymer is neutralized by the alkaline component, and is substantially deactivated. Therefore, the oxide layer of the substrate W is not dissolved by the action of the acid polymer. If the polymer film is heated, and the alkaline component is evaporated from the polymer film, the acid polymer will regain activity. In other words, the oxide layer of the substrate W is dissolved by the action of the acid polymer.

Preferably, the solvent remains in the polymer film without being completely evaporated. If so, the acid polymer in the polymer film can sufficiently function as an acid, thereby making it possible to efficiently remove the oxide layer. If the solvent remains, the polymer film exhibits neutrality when the alkaline component exists in the polymer film, and the polymer film exhibits acidity after the alkaline component is evaporated.

The electroconductive polymer functions as a medium for allowing the acid polymer to release protons (hydrogen ions) in the same way as the solvent. Therefore, it is possible to ionize the acid polymer and to allow the acid polymer to act on the oxide layer even if the solvent has been completely eliminated from the polymer film.

Additionally, it is possible to increase the concentration of the acid polymer component that has been dissolved into the solvent in the polymer film by moderately evaporating the solvent in the polymer film. This makes it possible to efficiently remove the oxide layer. Additionally, the chemical reaction to remove (dissolve) the oxide layer by means of the acid polymer is facilitated in proportion to an increase in temperature of the polymer film. In other words, the acid polymer has a property according to which the removal rate of the oxide layer becomes higher in proportion to an increase in temperature. Therefore, it is possible to efficiently remove the oxide layer by heating the polymer film formed on the upper surface of the substrate W.

A rinsing liquid functions as an oxidant removing liquid that removes (washes away) a liquid oxidant adhering to the upper surface of the substrate W, and functions also as a polymer removing liquid that dissolves the polymer film formed on the upper surface of the substrate W and then removes the resulting polymer film from the major surface of the substrate W.

The rinsing liquid is not limited to DIW. The rinsing liquid contains at least one among DIW, carbonic water, electrolyzed ion water, hydrochloric acid water having a diluted concentration (for example, not less than 1 ppm and not more than 100 ppm), ammonia water having a diluted concentration (for example, not less than 1 ppm and not more than 100 ppm), and restoration water (hydrogenated water). In other words, a liquid that is the same as the solvent of the polymer-containing liquid can be used as the rinsing liquid, and, if DIW is used both as the rinsing liquid and as the solvent of the polymer-containing liquid, the kind of liquids (substances) used here can be reduced.

The rinsing-liquid nozzle 11 is a stationary nozzle whose horizontal and vertical positions are fixed in the preferred embodiment. Unlike the preferred embodiment, the rinsing-liquid nozzle 11 may be a movable nozzle that is movable at least in the horizontal direction.

The rinsing-liquid nozzle 11 is connected to an end of a rinsing-liquid pipe 42 that guides a rinsing liquid to the rinsing-liquid nozzle 11. The other end of the rinsing-liquid pipe 42 is connected to a rinsing liquid tank (not shown). A rinsing-liquid valve 52A that opens and closes a flow path in the rinsing-liquid pipe 42 and a rinsing liquid flow-rate adjusting valve 52B that adjusts the flow rate of a rinsing liquid in this flow path are interposed in the rinsing-liquid pipe 42. When the rinsing-liquid valve 52A is opened, the rinsing liquid discharged from the discharge port of the rinsing-liquid nozzle 11 in a continuous flow lands on the upper surface of the substrate W.

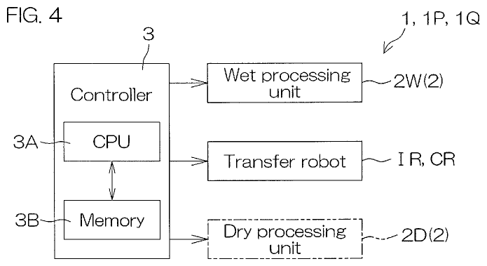

FIG. 4 is a block diagram for describing a configuration example concerning the control of the substrate processing apparatus 1. The controller 3 is provided with a microcomputer, and controls a to-be-controlled component provided in the substrate processing apparatus 1 in accordance with a predetermined control program. In detail, the controller 3 includes a processor (CPU) 3A and a memory 3B in which the control program is stored. The controller 3 is configured to perform a variety of control processes for substrate processing by allowing the processor 3A to execute the control program.

Particularly, the controller 3 is programmed to control each member (valve, motor, power source, etc.) of which the processing unit 2 is composed, the transfer robots IR and CR, etc. Valves are controlled by the controller 3, and, as a result, the presence or absence of the discharge of a fluid from a corresponding nozzle or the flow amount of a fluid discharged from a corresponding nozzle is controlled. The following steps are performed by allowing the controller 3 to control these constituents. In other words, the controller 3 is programmed to perform the following steps.

<Substrate Processing According to First Preferred Embodiment>

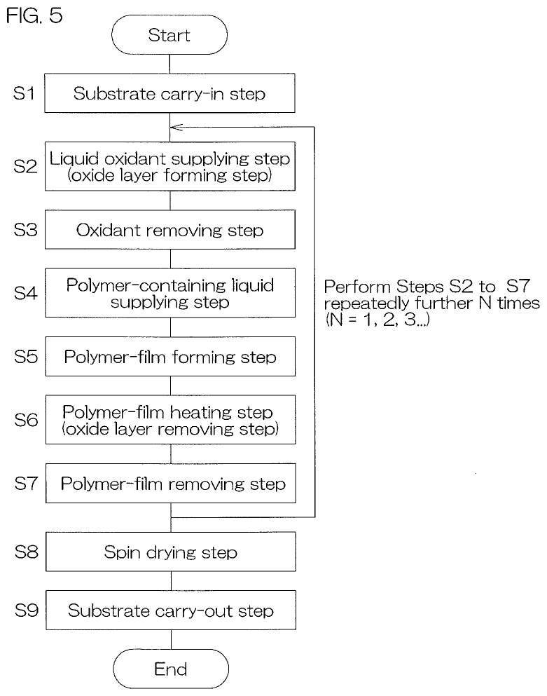

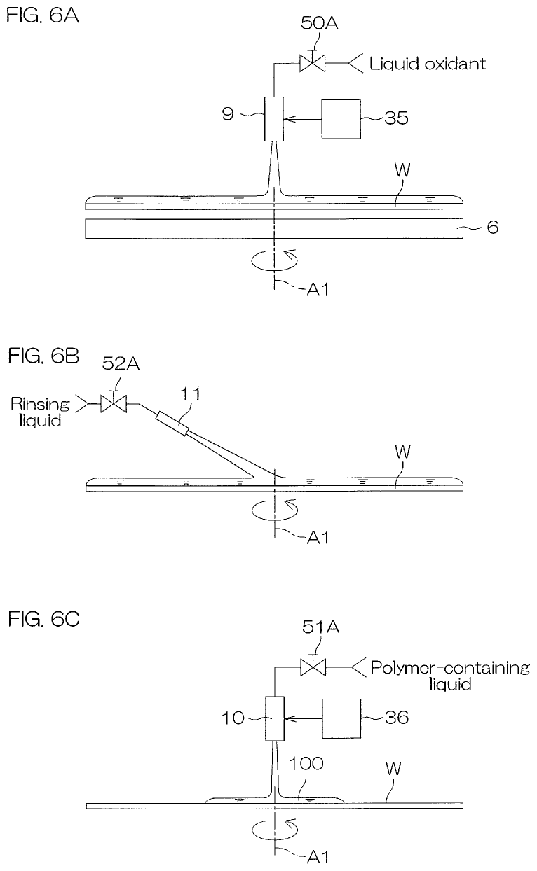

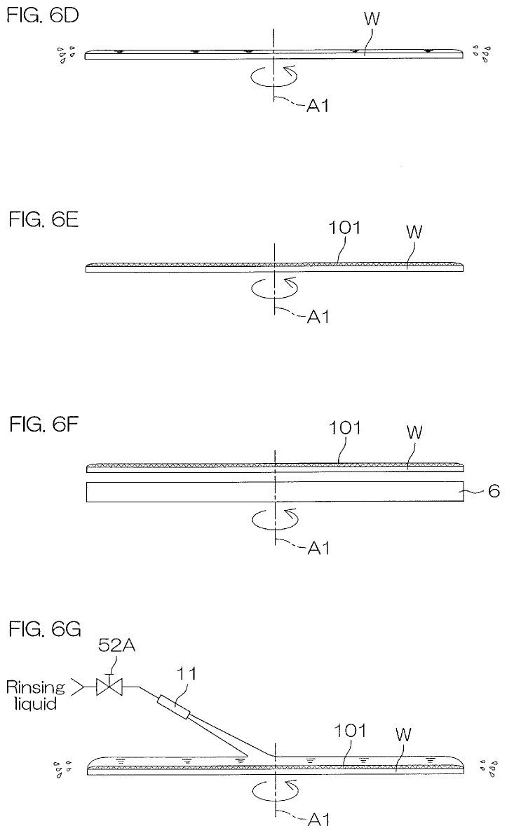

FIG. 5 is a flowchart for describing an example of substrate processing performed by the substrate processing apparatus 1. FIG. 6A to FIG. 6G are schematic views for describing an aspect of each step of substrate processing performed by the substrate processing apparatus 1.

Substrate processing performed by the substrate processing apparatus 1 will be hereinafter described with reference mainly to FIG. 3 and FIG. 5. Reference is made to FIG. 6A to FIG. 6G where appropriate.

First, a not-yet-processed substrate W is carried from the carrier C into the wet processing unit 2W by means of the transfer robots IR and CR (see FIG. 2A), and is delivered to the plurality of chuck pins 20 of the spin chuck 5 (substrate carry-in step: Step S1). The opening-closing unit 25 moves the plurality of chuck pins 20 to the closed position, and, as a result, the substrate W is gripped by the plurality of chuck pins 20. Thereby, the substrate W is horizontally held by the spin chuck 5 (substrate holding step). The spin motor 23 starts rotating the substrate W in a state in which the substrate W is held by the spin chuck 5 (substrate rotating step).

Thereafter, the transfer robot CR recedes outwardly from the wet processing unit 2W, and then a liquid oxidant supplying step (Step S2) of supplying a liquid oxidant to the upper surface of the substrate W is performed. In detail, first, the first nozzle moving unit 35 moves the oxidant nozzle 9 to a processing position. The processing position of the oxidant nozzle 9 is a center position at which, for example, the oxidant nozzle 9 faces a central region of the upper surface of the substrate W. The central region of the upper surface of the substrate W is a region including a center position of the upper surface of the substrate W and an area around the center position.

The oxidant valve 50A is opened in a state in which the oxidant nozzle 9 is placed at the processing position. Thereby, a liquid oxidant is supplied (discharged) from the oxidant nozzle 9 toward the central region of the upper surface of the substrate W as shown in FIG. 6A (liquid oxidant supplying step, liquid oxidant discharging step).

The liquid oxidant supplied to the upper surface of the substrate W spreads to the entirety of the upper surface of the substrate W because of a centrifugal force. The liquid oxidant that has reached a peripheral edge portion of the upper surface of the substrate W is discharged outwardly from the peripheral edge portion of the upper surface of the substrate W. An oxide layer is formed on the to-be-processed layer exposed from the upper surface of the substrate W by the supply of the liquid oxidant to the upper surface of the substrate W (oxide layer forming step, wet oxidation step). In this substrate processing, it is possible to oxidize the substrate W through a simple step of supplying the liquid oxidant to the substrate W.

The liquid oxidant may be heated through the substrate W by use of the heater unit 6 while supplying the liquid oxidant to the upper surface of the substrate W. In detail, the heater unit 6 is placed at the proximal position, and heats the substrate W that is rotating. The formation of the oxide layer is facilitated by heating the liquid oxidant (oxide-layer-formation facilitating step). Unlike FIG. 6A, the heater unit 6 may be placed at the retreat position while supplying the liquid oxidant.

The supply of the liquid oxidant is continuously performed during a predetermined period of time, and then an oxidant removing step of supplying a rinsing liquid to the upper surface of the substrate W and removing the liquid oxidant from the upper surface of the substrate W (Step S3) is performed. In detail, the oxidant valve 50A is closed, and the rinsing-liquid valve 52A is opened. Thereby, the supply of the liquid oxidant to the upper surface of the substrate W is stopped, and, instead, the supply (discharge) of a rinsing liquid to the upper surface of the substrate W from the rinsing-liquid nozzle 11 is started as shown in FIG. 6B (rinsing liquid supplying step, rinsing liquid discharging step). Thereby, the liquid oxidant on the substrate W is replaced by the rinsing liquid, and the liquid oxidant is removed from the upper surface of the substrate W.

The oxidant valve 50A is closed, and then the first nozzle moving unit 35 moves the oxidant nozzle 9 to the retreat position. When the oxidant nozzle 9 is placed at the retreat position, the oxidant nozzle 9 is situated outside the processing cup 7 without facing the upper surface of the substrate W in a plan view.

The supply of the rinsing liquid is continuously performed during a predetermined period of time, and then a polymer-containing liquid supplying step (Step S4) of supplying a polymer-containing liquid to the upper surface of the substrate W is performed.

In detail, the second nozzle moving unit 36 moves the polymer-containing liquid nozzle 10 to the processing position. The processing position of the polymer-containing liquid nozzle 10 is, for example, a center position at which the polymer-containing liquid nozzle 10 faces the central region of the upper surface of the substrate W. The polymer-containing liquid valve 51A is opened in a state in which the polymer-containing liquid nozzle 10 is placed at the processing position. Thereby, a polymer-containing liquid is supplied (discharged) from the polymer-containing liquid nozzle 10 toward the central region of the upper surface of the substrate W as shown in FIG. 6C (polymer-containing liquid supplying step, polymer-containing liquid discharging step). The polymer-containing liquid discharged from the polymer-containing liquid nozzle 10 lands on the central region of the upper surface of the substrate W.

When the polymer-containing liquid is supplied to the upper surface of the substrate W, the substrate W may be rotated at a low speed (for example, 10 rpm) (low-speed rotation step). Alternatively, when the polymer-containing liquid is supplied to the upper surface of the substrate W, the rotation of the substrate W may be stopped. The polymer-containing liquid supplied to the substrate W stays in the central region of the upper surface of the substrate W by reducing the rotation speed of the substrate W to a low speed or by stopping the rotation of the substrate W. This makes it possible to make the polymer-containing liquid small in amount used.

Thereafter, a polymer-film forming step (Step S5) is performed in which a solid or semisolid polymer film 101 (see FIG. 6E) is formed on the upper surface of the substrate W by evaporating at least a portion of the solvent contained in the polymer-containing liquid on the upper surface of the substrate W as shown in FIG. 6D and FIG. 6E.

In detail, the polymer-containing liquid valve 51A is closed, and the discharge of the polymer-containing liquid from the polymer-containing liquid nozzle 10 is stopped. The polymer-containing liquid valve 51A is closed, and then the polymer-containing liquid nozzle 10 is moved to the retreat position by means of the second nozzle moving unit 36. When the polymer-containing liquid nozzle 10 is moved to the retreat position, the polymer-containing liquid nozzle 10 does not face the upper surface of the substrate W, and is placed outside the processing cup 7 in a plan view.

The polymer-containing liquid valve 51A is closed, and then the rotation of the substrate W is accelerated so that the rotation speed of the substrate W reaches a predetermined spin-off speed as shown in FIG. 6D (rotation acceleration step). The spin-off speed is, for example, 1500 rpm. The rotation of the substrate W at the spin-off speed is continued during, for example, 30 seconds. The polymer-containing liquid staying in the central region of the upper surface of the substrate W is expanded toward the peripheral edge portion of the upper surface of the substrate W by means of a centrifugal force caused by the rotation of the substrate W, and is expanded to the entirety of the upper surface of the substrate W. A portion of the polymer-containing liquid on the substrate W scatters outwardly from the peripheral edge portion of the substrate W, and the liquid film of the polymer-containing liquid on the substrate W is thinned as shown in FIG. 6D (spin-off step). The polymer-containing liquid on the upper surface of the substrate W is not necessarily required to scatter outwardly from the substrate W, and is merely required to be spread to the entirety of the upper surface of the substrate W by means of the action of the centrifugal force of the rotation of the substrate W.

The centrifugal force caused by the rotation of the substrate W acts not only on the polymer-containing liquid on the substrate W but also on a gas contiguous to the polymer-containing liquid on the substrate W. Therefore, an airflow in which this gas proceeds toward the peripheral edge side from the central side of the upper surface of the substrate W is formed by the action of the centrifugal force. Because of this airflow, the solvent that is in a gaseous state and that is contiguous to the polymer-containing liquid on the substrate W is excluded from an atmosphere contiguous to the substrate W. Therefore, the evaporation (volatilization) of the solvent from the polymer-containing liquid on the substrate W is facilitated, and a solid or semisolid polymer film 101 is formed as shown in FIG. 6E (polymer-film forming step). Thus, both the polymer-containing liquid nozzle 10 and the spin motor 23 function as a polymer-film forming unit.

The polymer film 101 is higher in viscosity than the polymer-containing liquid, and therefore the polymer film 101 stays on the substrate W without being completely excluded from on the substrate W although the substrate W is rotating. Immediately after forming the polymer film 101, an alkaline component is contained in the polymer film 101. Therefore, the acid polymer in the polymer film 101 is in a substantially deactivated state, and therefore the oxide layer is hardly removed.

Thereafter, a polymer-film heating step (Step S6) of heating the polymer film 101 on the substrate W. In detail, the heater unit 6 is placed at the proximal position, and the substrate W is heated as shown in FIG. 6F (substrate heating step, heater heating step).

The polymer film 101 formed on the substrate W is heated through the substrate W. The polymer film 101 is heated, and, as a result, the alkaline component is evaporated, and the acid polymer regains activity (alkali component evaporation step, alkali component removing step). Therefore, the etching of the substrate W is started by the action of the acid polymer in the polymer film 101 (etching start step, etching step).

In detail, the removal of the oxide layer formed at the surface layer portion of the upper surface of the substrate W is started (oxide layer removal start step, oxide layer removing step). Until the polymer film 101 is heated after the polymer film 101 is formed, the acid polymer is neutralized by the alkaline component, and is in a substantially deactivated state. Therefore, until the polymer film 101 is heated after the polymer film 101 is formed, the etching of the substrate W is hardly started.

The acid polymer has a property in which the removal rate of the oxide layer becomes higher in proportion to an increase in temperature as described above. Therefore, even after the alkaline component is removed from the polymer film 101, the removal of the oxide layer by means of the acid polymer is facilitated by continuously heating the polymer film 101 (removal facilitating step).

The polymer film 101 is heated, and, as a result, the solvent in the polymer film 101 is evaporated. Therefore, the concentration of the acid polymer that has been dissolved into the solvent in the polymer film 101 becomes higher (polymer concentrating step). Thereby, the concentration of the acid polymer rises, and the removal rate of the oxide layer caused by the action of the acid polymer is improved.

Preferably, the heating temperature of the substrate W is lower than the boiling point of the solvent in the polymer film 101. If so, it is possible to moderately evaporate the solvent from the polymer film 101 on the substrate W. Therefore, it is possible to raise the concentration of the acid polymer that has been dissolved into the solvent in the polymer film 101. Additionally, it is possible to prevent the solvent from being thoroughly evaporated and from being completely removed from inside of the polymer film 101.

Thereafter, the polymer film 101 is heated through the substrate W during a predetermined period of time, and then a polymer-film removing step (Step S7) of removing the polymer film 101 on the substrate W is performed. In detail, the heater unit 6 recedes to the retreat position, and the rinsing-liquid valve 52A is opened. Thereby, a rinsing liquid is supplied (discharged) from the rinsing-liquid nozzle 11 toward the central region of the upper surface of the substrate W on which the polymer film 101 is formed as shown in FIG. 6G (rinsing liquid supplying step, rinsing liquid discharging step).

The polymer film 101 on the substrate W is dissolved by the rinsing liquid supplied to the substrate W (polymer-film dissolving step). The rinsing liquid is continuously supplied to the substrate W, and, as a result, the polymer film 101 is removed from the upper surface of the substrate W (polymer-film removing step). The polymer film 101 is removed from the upper surface of the substrate W both by the dissolving action made by the rinsing liquid and by the flow of the rinsing liquid created on the upper surface of the substrate W (rinsing step).

Herein, “N” of FIG. 5 denotes a natural number. Therefore, cycle processing in which a process ranging from the liquid oxidant supplying step (Step S2) to the polymer-film removing step (Step S7) is set as “one cycle” is further performed once or more after the first polymer-film removing step is completed. Thereby, the oxide layer forming step and the oxide layer removing step are alternately repeated. In other words, the oxide layer forming step and the oxide layer removing step are each alternately performed a plurality of times.

The cycle processing is performed a plurality of times, and a spin drying step (Step S8) subsequent to the last polymer-film removing step (Step S7) is performed.

In detail, the rinsing-liquid valve 52A is closed, and the supply of the rinsing liquid to the upper surface of the substrate W is stopped. Thereafter, the spin motor 23 accelerates the rotation of the substrate W, and the substrate W is rotated at a high speed. The substrate W is rotated at a drying speed, e.g., 1500 rpm. As a result, a great centrifugal force acts on the rinsing liquid on the substrate W, and the rinsing liquid on the substrate W is shaken off toward an area around the substrate W.

Thereafter, the spin motor 23 stops the rotation of the substrate W. The transfer robot CR enters the wet processing unit 2W, and receives an already-processed substrate W from the plurality of chuck pins 20, and carries this substrate W out of the wet processing unit 2W (substrate carry-out step: Step S9). This substrate W is delivered from the transfer robot CR to the transfer robot IR, and is housed in the carrier C by means of the transfer robot IR.

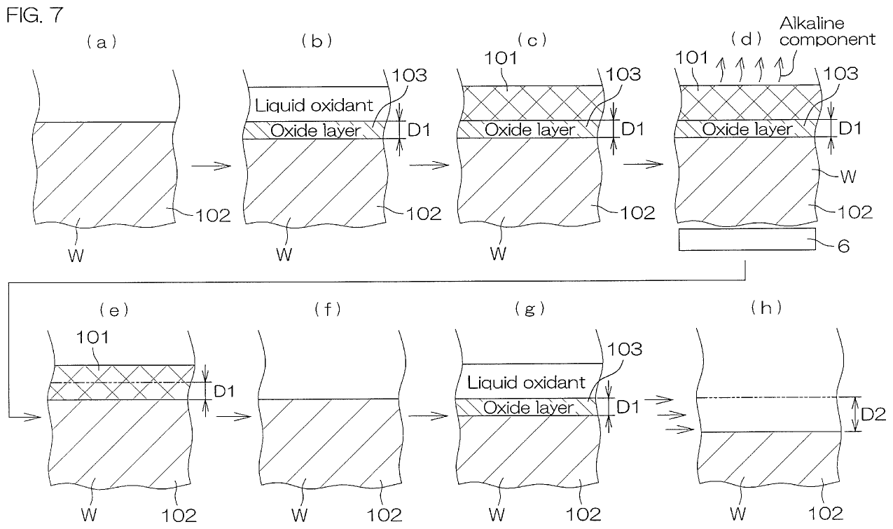

FIG. 7 is a schematic view for describing a change in the surface layer portion of the upper surface of the substrate W caused by allowing the oxide layer forming step and the oxide layer removing step to be alternately repeated in the substrate processing.

The oxide layer 103 is formed at the surface layer portion of the to-be-processed layer 102 by supplying a liquid oxidant, such as hydrogen peroxide water, to the upper surface of the substrate W as shown in FIG. 7(a) and FIG. 7(b) (oxide layer forming step). Thereafter, a polymer-containing liquid is supplied to the upper surface of the substrate W, and at least a portion of a solvent contained in the polymer-containing liquid on the substrate W is evaporated, and, as a result, the polymer film 101 is formed on the upper surface of the substrate W as shown in FIG. 7(c) (polymer-film forming step). Thereafter, an alkaline component is evaporated by heating the polymer film 101, and the alkaline component is removed from the polymer film 101 as shown in FIG. 7(d) (alkali component evaporating step, alkali component removing step). The oxide layer 103 is dissolved by the action of the acid polymer contained in the polymer film 101 on the upper surface of the substrate W, and is dissolved into the polymer film 101. Thereby, the oxide layer 103 is selectively removed from the upper surface of the substrate W as shown in FIG. 7(e) (oxide layer removing step). FIG. 7(f) shows a state of a front surface of the to-be-processed layer 102 from which the polymer film 101 has been removed thereafter.

The oxide layer forming step and the oxide layer removing step are each performed once, and, as a result, the thickness of the to-be-processed layer 102 that is oxidized is substantially constant (see FIG. 7(b)). Therefore, the thickness (amount of etching D1) of the oxide layer 103 that is removed is also substantially constant (see FIG. 7(e)).

As shown in FIG. 7(g), the cycle processing is performed a plurality of times of cycles, and, as a result, a portion, which has a thickness D2 corresponding to the product of the thickness D1 and the number of cycles, of the to-be-processed layer 102 is removed from the substrate W (D2=D1×the number of cycles). The amount etched of the to-be-processed layer 102 corresponds to the thickness D2 by performing the cycle processing a plurality of times of cycles. Therefore, it is possible to achieve a desired amount of etching (which is equal in amount to the thickness D2) by adjusting the number of times by which the oxide layer forming step and the oxide layer removing step are repeatedly performed.

As thus described, the process of etching the to-be-processed layer 102 stepwisely at a predetermined amount etched is referred to as “digital etching.” Additionally, the process of etching the to-be-processed layer 102 by repeatedly performing the oxide layer forming step and the oxide layer removing step is referred to as “cycle etching.”

According to the first preferred embodiment, the controller 3 controls the oxidant nozzle 9, the polymer-containing liquid nozzle 10, the spin base 21, etc., and, as a result, the oxidization of the to-be-processed layer (formation of the oxide layer) and the formation of the polymer film 101 are alternately repeated.

Thereby, the formation of the oxide layer 103 and the removal of the oxide layer 103 are alternately repeated, thus making it possible to accurately etch the to-be-processed layer 102. Additionally, according to this substrate processing method, the to-be-processed layer 102 is etched by the acid polymer contained in the polymer film 101 formed on the upper surface of the substrate W. The polymer film 101 is semisolid or solid, and therefore the polymer film 101 stays on the upper surface of the substrate W more easily than a liquid. Therefore, it is possible to make a substance (hydrofluoric acid or acid polymer) required to etch the to-be-processed layer 102 smaller in amount used than in a case in which the oxide layer 103 is removed by an etching liquid that contains a low-molecular-weight etching component, such as hydrofluoric acid.

Therefore, it is possible to make a substance required to etch the substrate W smaller in amount used while accurately etching the to-be-processed layer 102.

The following effects are fulfilled by etching the to-be-processed layer 102 by use of the polymer film 101 containing an acid polymer in the same way as in the first preferred embodiment.

When the oxide layer 103 is removed by a continuously-flowing etching liquid, the temperature of the etching liquid becomes low during a period of time during which the etching liquid proceeds from the central side of the upper surface of the substrate W toward the peripheral edge side. Therefore, the amount of etching (amount removed) in the peripheral edge region of the upper surface of the substrate W becomes smaller than the amount of etching in the central region of the upper surface of the substrate W because of a drop in temperature of the etching liquid, and there is a concern that the uniformity of the amount of etching at each position of the upper surface of the substrate W will be reduced.

On the other hand, according to the first preferred embodiment, the entirety of the upper surface of the substrate W is covered by the semisolid or solid polymer film 101, and the oxide layer 103 is removed by the action of the acid polymer in the polymer film 101. Therefore, the acid polymer does not move from the central side of the upper surface of the substrate W toward the peripheral edge side in a state in which the polymer film 101 is formed, and therefore the temperature of a portion, which is contiguous to each position of the upper surface of the substrate W, of the polymer film 101 changes substantially uniformly. Therefore, it is possible to improve uniformity in the amount of etching.

Unlike the first preferred embodiment, in a configuration in which the oxide layer 103 is removed by a continuously-flowing etching liquid, there is a case in which a liquid that has entered the trench 122 cannot be sufficiently replaced by the etching liquid if the width L of the trench 122 formed in the upper surface of the substrate W is narrow. Therefore, if the plurality of trenches 122 that differ in the width L from each other are formed in the upper surface of the substrate W, variations will occur in the degree of replacement of a liquid, which has entered the trench 122, by the etching liquid, and the uniformity in the amount of etching in the upper surface of the substrate W will decrease.

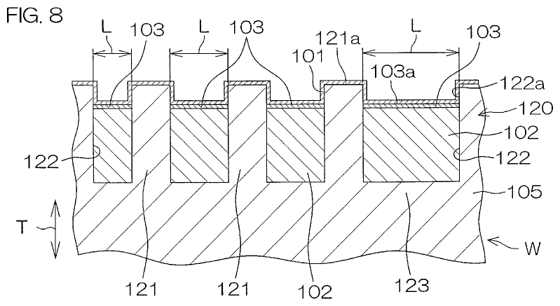

On the other hand, according to the first preferred embodiment, the polymer film 101 is formed to follow both the to-be-processed layer 102 and the trench 122 regardless of the width L of the trench 122 as shown in FIG. 8. In detail, the polymer film 101 is formed along a front surface 103a of the oxide layer 103, a side surface 122a of the trench 122, and a top portion 121a of the structure 121. Therefore, it is possible to reduce variations in the amount of etching applied to the to-be-processed layer 102 between the trenches 122 even if the trenches 122 having mutually-different widths L are formed.

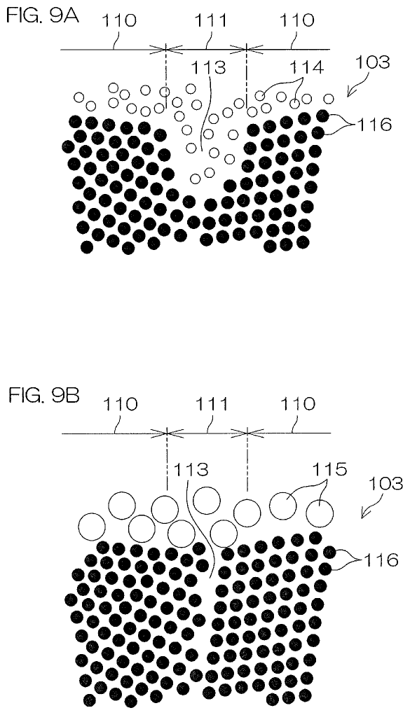

The distance between constitutive substances 116 of which the oxide layer 103 is composed in the grain boundary 111 is wider than the distance between constitutive substances 116 in the crystal grain 110 as shown in FIG. 9A and FIG. 9B. Therefore, a gap 113 exists between the constitutive substances 116 in the grain boundary 111. The constitutive substance 116 is, for example, a molecule, and is, typically, a copper oxide molecule.

Unlike the first preferred embodiment, a low-molecular-weight etching component 114 is liable to enter the gap 113 existing in the grain boundary 111 of the substrate W if the oxide layer 103 is removed by an etching liquid that contains the low-molecular-weight etching component 114, such as hydrofluoric acid, as shown in FIG. 9A. Therefore, it is easy to remove the oxide layer 103 in a place having a large grain-boundary density (in the trench 122 having a narrow width L), and it is difficult to remove the oxide layer 103 in a place having a small grain-boundary density (in the trench 122 having a wide width L). Therefore, the to-be-processed layer 102 cannot be easily etched evenly, and the roughness (surface roughness) of the upper surface of the substrate W increases.

On the other hand, according to the first preferred embodiment, an acid polymer 115 that is a high-molecular-weight etching component cannot more easily enter the gap 113 existing in the grain boundary 111 than the low-molecular-weight etching component 114 as shown in FIG. 9B. Therefore, it is possible to evenly etch the to-be-processed layer 102 regardless of the grain-boundary density. It is possible to reduce the roughness of the upper surface of the substrate W.

Additionally, the following effects are fulfilled according to the first preferred embodiment.

According to the first preferred embodiment, the acid polymer in the polymer film 101 regains activity by heating the polymer film 101 and by evaporating the alkaline component, and etching is started. Therefore, it is possible to accurately etch the substrate W. Particularly, it is possible to accurately control the starting timing of the etching of the substrate W.

Additionally, according to the first preferred embodiment, it is possible to facilitate ionization of the acid polymer in the polymer film 101 by the action of the electroconductive polymer. Therefore, it is possible to allow the acid polymer to effectively act on the oxide layer 103.

Additionally, in the first preferred embodiment, the polymer film 101 is removed from the upper surface of the substrate W after the oxide layer removing step is completed and before the oxide layer forming step subsequent to the oxide layer removing step is started. The formation of the oxide layer 103 is started after the polymer film 101 is removed from the substrate W, thereby making it possible to prevent the oxide layer 103 from being removed while oxidizing the to-be-processed layer 102. In detail, it is possible to prevent the oxide layer 103 formed in the oxide layer forming step from being removed by an acid polymer remaining on the substrate W, thereby making it possible to prevent the formation and the removal of the oxide layer 103 from occurring in a chain-reaction manner in the oxide layer forming step. Therefore, it is possible to prevent the amount of the to-be-processed layer 102 etched from becoming larger than envisioned. In other words, the to-be-processed layer 102 is enabled to be etched more highly accurately.

Additionally, according to the first preferred embodiment, a liquid oxidant is removed from the upper surface of the substrate W by supplying a rinsing liquid to the upper surface of the substrate W after the oxide layer forming step and before the oxide layer removing step. The removal of the oxide layer 103 is started after the liquid oxidant is removed from the substrate W, thereby making it possible to prevent the oxide layer 103 from being formed while etching the surface layer portion of the major surface of the substrate W. In detail, it is possible to prevent the oxide layer 103 from being further formed by the oxidant remaining on the substrate W while the oxide layer 103 is being removed by the acid polymer contained in the polymer film 101, thereby making it possible to prevent the formation and the removal of the oxide layer 103 from occurring in a chain-reaction manner in the oxide layer removing step. Therefore, it is possible to prevent the amount of the to-be-processed layer 102 etched from becoming larger than envisioned. In other words, the to-be-processed layer 102 is enabled to be etched more highly accurately.

Additionally, according to the first preferred embodiment, it is possible to facilitate the removal of the oxide layer 103 by heating the polymer film 101, thereby making it possible to reduce a period of time required for substrate processing.

<Another Example of Substrate Processing According to First Preferred Embodiment>

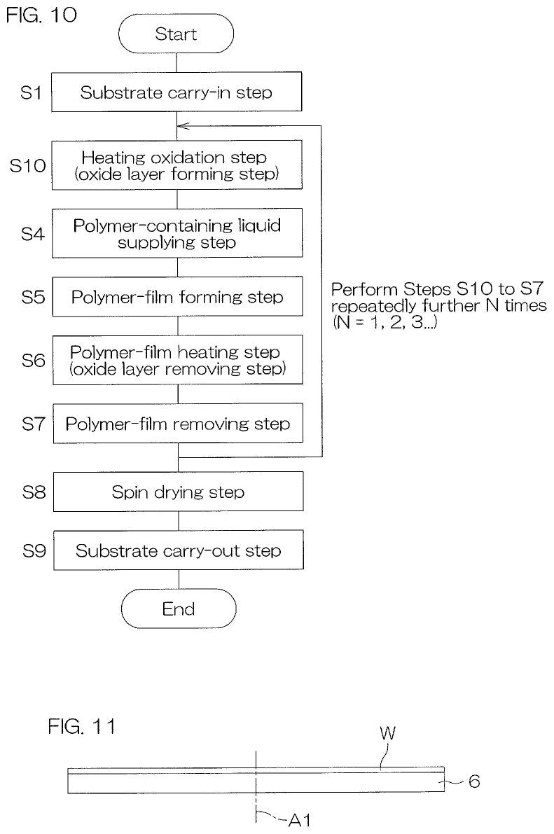

FIG. 10 is a flowchart for describing one other example of substrate processing performed by the substrate processing apparatus 1. FIG. 11 is a schematic view for describing an aspect of a substrate W when the substrate processing of the other example is performed.

The substrate processing of FIG. 10 differs from the substrate processing of FIG. 5 mainly in that a heating oxidation step (Step S10) of forming an oxide layer by allowing the heater unit 6 to perform heating is performed instead of the liquid oxidant supplying step (Step S2) and the oxidant removing step (Step S3).

In detail, a substrate W is carried into the wet processing unit 2W, and then the substrate W held by the spin chuck 5 is heated to a predetermined oxidizing temperature by means of the heater unit 6 (heating oxidation step). Thereby, a to-be-processed layer exposed from the upper surface of the substrate W is oxidized, and an oxide layer is formed (oxide layer forming step). The predetermined oxidizing temperature is, for example, not less than 100° C. and not more than 400° C. The oxide layer formed by heating has a thickness of, for example, not less than 10 nm and not more than 20 nm.

The heater unit 6 is placed at, for example, the contact position as shown in FIG. 11. Thereby, the substrate W can be heated to such a high-temperature as to oxidize the to-be-processed layer. In this substrate processing, the heater unit 6 functions as a substrate oxidizing unit.

Thereafter, the polymer-containing liquid supplying step (Step S4) is performed. In detail, the second nozzle moving unit 36 moves the polymer-containing liquid nozzle 10 to the processing position, and the polymer-containing liquid valve 51A is opened. Thereby, a polymer-containing liquid is supplied to the upper surface of the substrate W.

Thereafter, the polymer-film forming step (Step S5) and the polymer-film heating step (Step S6) are performed. Preferably, the removal of the oxide layer 103 (see FIG. 1) in the polymer-film heating step (Step S6) is performed while heating the substrate W at a lower temperature than in the heating oxidation step. Preferably, for example, heating is performed in the polymer-film heating step (Step S6) in a state in which the heater unit 6 is placed at the proximal position away from the substrate W not at the contact position as shown in FIG. 6F. This makes it possible to facilitate the removal of the oxide layer by means of the polymer film 101 while restraining the oxidation of the surface layer portion of the upper surface of the substrate W (removal facilitating step).

If this substrate processing is employed, it is possible to oxidize the to-be-processed layer 102 (see FIG. 1) exposed from the upper surface of the substrate W by heating the substrate W. In other words, it is possible to form the oxide layer 103 (see FIG. 1) without using a liquid. Therefore, it is possible to make a substance (oxidant) for use in etching the to-be-processed layer 102 small in amount used. Additionally, the formation and the removal of the oxide layer 103 are performed in a state in which the substrate W is being held by the same spin chuck 5. Therefore, there is no need to move the substrate W, and therefore it is possible to more swiftly remove the oxide layer 103 than a configuration in which the formation and the removal of the oxide layer 103 are respectively performed in a state in which the substrate W is being held by mutually different spin chucks.

Additionally, it is possible to facilitate the removal of the oxide layer 103 by using the amount of heat of the substrate W, which has been heated to oxidize the substrate W, for heating the polymer film 101. Consequently, it is possible to reduce a period of time required for substrate processing.

Additionally, if this substrate processing is employed, it is possible to also use the heater unit 6, which is used for the formation of the oxide layer 103, for heating by which the removal of the oxide layer 103 is facilitated. Therefore, in order to facilitate the removal of the oxide layer 103, there is no need to provide a heater unit differing from the heater unit 6 used for heating by which the substrate W is oxidized, and therefore it is possible to simplify substrate processing.

Additionally, the heater unit 6 that is used for heating by which the oxide layer 103 is formed is also used for heating by which the removal of the oxide layer 103 is facilitated, and, as a result, it is possible to use the amount of heat, which has been given to the heater unit 6 for the formation of the oxide layer 103, for the removal of the oxide layer 103. Therefore, it is possible to more efficiently facilitate the etching of the to-be-processed layer 102 than a configuration in which a heater unit differing from the heater unit 6 used to oxidize the oxide layer 103 is provided to facilitate the removal of the oxide layer 103.

The process may return to the heating oxidation step (Step S10) after the spin drying step (Step S8) without returning to the heating oxidation step (Step S10) after the polymer-film removing step (Step S7) unlike the substrate processing shown in FIG. 10. Likewise, in the substrate processing shown in FIG. 5, the process may return to the liquid oxidant supplying step (Step S2) after the spin drying step (Step S8).

Additionally, the substrate processing shown in FIG. 5 and the substrate processing shown in FIG. 10 may be combined together. For example, the heating oxidation step (Step S10) may be performed after the steps ranging from the liquid oxidant supplying step (Step S2) to the polymer-film removing step (Step S7) are performed, or the liquid oxidant supplying step (Step S2) may be performed after the steps ranging from the heating oxidation step (Step S10) to the polymer-film removing step (Step S7) are performed.

<Polymer-Containing Liquid Supplying Method>

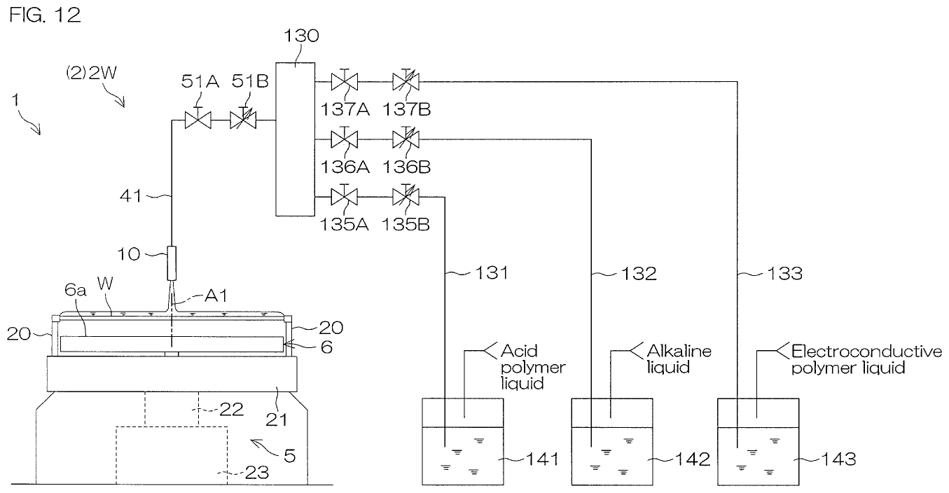

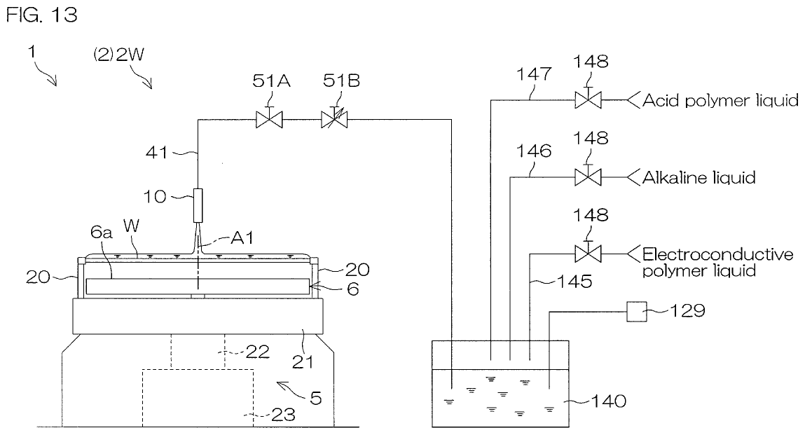

FIG. 12 and FIG. 13 are schematic views for describing a first example and a second example, respectively, of a method of supplying a polymer-containing liquid to the substrate. For descriptive convenience, the spin chuck 5, the heater unit 6, the processing cup 7, the oxidant nozzle 9, and the rinsing-liquid nozzle 11 are not shown and are omitted in FIG. 12 and FIG. 13.

In the first example of the supply method shown in FIG. 12, an acid polymer liquid, an alkaline liquid, and an electroconductive polymer liquid are mixed together in a mixing pipe 130, and a polymer-containing liquid is formed, and the polymer-containing liquid formed in the mixing pipe 130 is discharged from the polymer-containing liquid nozzle 10, and, as a result, is supplied to the upper surface of the substrate W (polymer-containing liquid supplying step). The mixing pipe 130 is a pipe for mixing a plurality of liquids, and is, for example, a mixing valve.

The acid polymer liquid is a liquid that contains an acid polymer and a solvent, and the alkaline liquid is a liquid that contains an alkaline component and a solvent. The electroconductive polymer liquid is a liquid that contains an electroconductive polymer and a solvent. Preferably, the solvents contained in these liquids are the same kind of liquid, and, preferably, this liquid is, for example, DIW.

The acid polymer liquid is supplied from the acid-polymer liquid tank 141 to the mixing pipe 130 through an acid-polymer liquid pipe 131. The alkaline liquid is supplied from an alkaline liquid tank 142 to the mixing pipe 130 through an alkaline liquid pipe 132. The electroconductive polymer liquid is supplied from an electroconductive-polymer liquid tank 143 to the mixing pipe 130 through an electroconductive-polymer liquid pipe 133. The polymer-containing liquid formed in the mixing pipe 130 is supplied to the polymer-containing liquid nozzle 10 through the polymer-containing liquid pipe 41. A plurality of valves (an acid-polymer liquid valve 135A, an alkaline liquid valve 136A, and an electroconductive-polymer liquid valve 137A) that open and close flow paths in corresponding pipes are interposed in the acid-polymer liquid pipe 131, the alkaline liquid pipe 132, and the electroconductive-polymer liquid pipe 133, respectively. A plurality of flow-rate adjusting valves (an acid-polymer liquid flow-rate adjusting valve 135B, an alkaline liquid flow-rate adjusting valve 136B, and an electroconductive-polymer liquid flow-rate adjusting valve 137B) that adjust flow rates of liquids in corresponding pipes are interposed in the acid-polymer liquid pipe 131, the alkaline liquid pipe 132, and the electroconductive-polymer liquid pipe 133, respectively.

In the second example of the method of supplying a polymer-containing liquid shown in FIG. 13, the polymer-containing liquid is supplied from a polymer-containing liquid tank 140 to the polymer-containing liquid nozzle 10 through the polymer-containing liquid pipe 41. An acid polymer liquid, an alkaline liquid, and an electroconductive polymer liquid are supplementarily supplied to the polymer-containing liquid tank 140 through an acid-polymer liquid supplementary pipe 145, an alkaline liquid supplementary pipe 146, and an electroconductive-polymer liquid supplementary pipe 147, respectively. The acid polymer liquid, the alkaline liquid, and the electroconductive polymer liquid are mixed together in the polymer-containing liquid tank 140, and, as a result, a polymer-containing liquid is formed.

A pH meter 129 may be provided at the polymer-containing liquid tank 140. The controller 3 may perform feedback control on the basis of pH detected by the pH meter 129. The feedback control is performed so that the pH of the polymer-containing liquid maintains neutrality by adjusting a plurality of supplementary valves 148 interposed in the plurality of supplementary pipes (acid-polymer liquid supplementary pipe 145, alkaline liquid supplementary pipe 146, and electroconductive-polymer liquid supplementary pipe 147), respectively.

<Modification of Substrate Processing Apparatus according to First Preferred Embodiment>

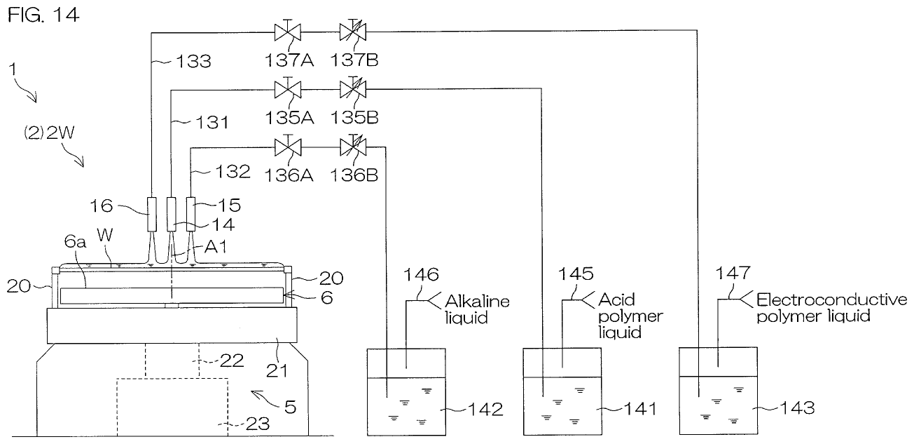

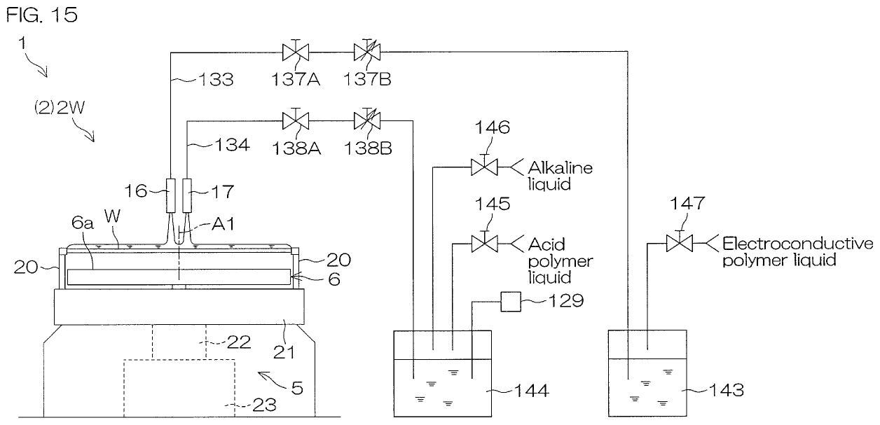

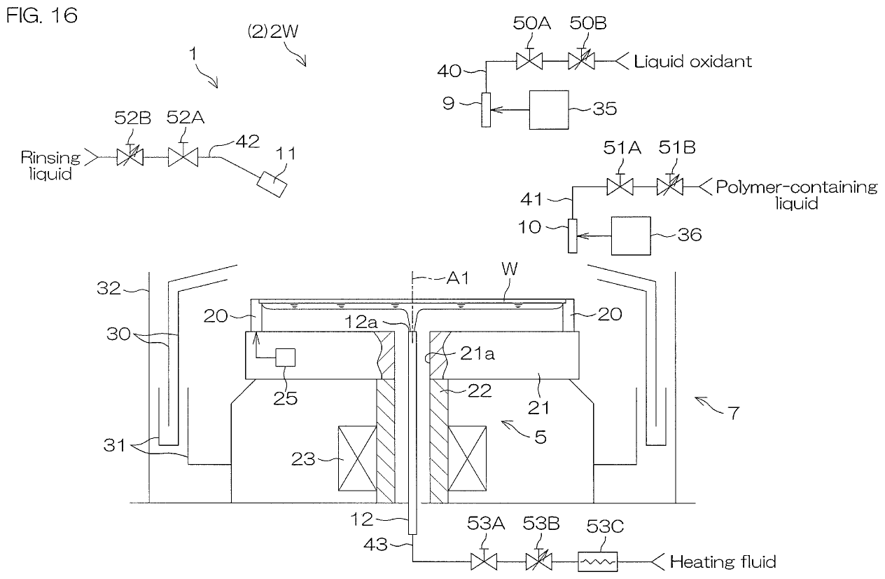

FIG. 14 to FIG. 16 are schematic views for describing a first modification to a third modification of the wet processing unit 2W, respectively. FIG. 14 is a schematic view for describing the first modification of the wet processing unit 2W. In FIG. 14, the same reference sign as in FIG. 1 to FIG. 13 mentioned above is assigned to a constituent equivalent to each constituent shown in FIG. 1, etc., and a description of the constituent is omitted. The same applies to FIG. 15 and FIG. 16 described later.

Unlike the example of FIG. 3, the wet processing unit 2W may be configured so that a polymer-containing liquid is formed on the upper surface of the substrate W as shown in FIG. 14. For descriptive convenience, the processing cup 7, the oxidant nozzle 9, and the rinsing-liquid nozzle 11 are omitted, and are not shown in FIG. 14 and FIG. 15.

The wet processing unit 2W includes an acid-polymer liquid nozzle 14 that supplies an acid polymer liquid to the upper surface of the substrate W held by the spin chuck 5, an alkaline liquid nozzle 15 that supplies an alkaline liquid to the upper surface of the substrate W held by the spin chuck 5, and an electroconductive-polymer liquid nozzle 16 that supplies an electroconductive polymer liquid to the upper surface of the substrate W held by the spin chuck 5, instead of the polymer-containing liquid nozzle 10. These nozzles may be movable in the horizontal direction in the same way as the polymer-containing liquid nozzle 10.

The acid-polymer liquid pipe 131 that guides an acid polymer liquid contained in the acid-polymer liquid tank 141 to the acid-polymer liquid nozzle 14 is connected to the acid-polymer liquid nozzle 14. The alkaline liquid pipe 132 that guides an alkaline liquid contained in the alkaline liquid tank 142 to the alkaline liquid nozzle 15 is connected to the alkaline liquid nozzle 15. The electroconductive-polymer liquid pipe 133 that guides an electroconductive polymer liquid contained in the electroconductive-polymer liquid tank 143 to the electroconductive-polymer liquid nozzle 16 is connected to the electroconductive-polymer liquid nozzle 16.

The plurality of valves (the acid-polymer liquid valve 135A, the alkaline liquid valve 136A, and the electroconductive-polymer liquid valve 137) that open and close flow paths in corresponding pipes are interposed in the acid-polymer liquid pipe 131, the alkaline liquid pipe 132, and the electroconductive-polymer liquid pipe 133, respectively. The plurality of flow-rate adjusting valves (the acid-polymer liquid flow-rate adjusting valve 135B, the alkaline liquid flow-rate adjusting valve 136B, and the electroconductive-polymer liquid flow-rate adjusting valve 137B) that adjust flow rates of liquids in corresponding pipes are interposed in the acid-polymer liquid pipe 131, the alkaline liquid pipe 132, and the electroconductive-polymer liquid pipe 133, respectively.

In a first modification of the substrate processing apparatus 1 shown in FIG. 14, an acid polymer liquid, an alkaline liquid, and an electroconductive polymer liquid are discharged from the nozzles corresponding thereto, and land on the upper surface of the substrate W in the polymer-containing liquid supplying step (Step S4). The acid polymer liquid, the alkaline liquid, and the electroconductive polymer liquid are mixed together on the upper surface of the substrate W, and a polymer-containing liquid is formed.

FIG. 15 is a schematic view for describing a second modification of the wet processing unit 2W. In the wet processing unit 2W of the second modification, a polymer-containing liquid is formed on the upper surface of the substrate W as shown in FIG. 15 in the same way as in the first modification of FIG. 14. It should be noted that, unlike the first modification, the alkaline liquid nozzle 15 and the acid-polymer liquid nozzle 14 are not provided, and a neutral liquid nozzle 17 from which a neutral liquid, which is a liquid obtained by mixing an alkaline liquid and an acid polymer liquid together, is supplied to the upper surface of the substrate W is provided. The neutral liquid nozzle 17 is movable in the horizontal direction.

A neutral liquid pipe 134 that guides a neutral liquid contained in a neutral liquid tank 144 to the neutral liquid nozzle 17 is connected to the neutral liquid nozzle 17. A neutral liquid valve 138A that opens and closes a flow path in the neutral liquid pipe 134 is interposed in the neutral liquid pipe 134. A neutral liquid flow-rate adjusting valve 138B that adjusts the flow rate of a neutral liquid in the neutral liquid pipe 134 is interposed in the neutral liquid pipe 134. An acid polymer liquid and an alkaline liquid are supplementarily supplied to the neutral liquid tank 144 through the acid-polymer liquid supplementary pipe 145 and the alkaline liquid supplementary pipe 146, respectively.

A pH meter 129 may be provided at the neutral liquid tank 144. The controller 3 may perform feedback control on the basis of pH detected by the pH meter 129. The feedback control is performed so that the pH of the neutral liquid maintains neutrality by adjusting a plurality of supplementary valves 148 interposed in the plurality of supplementary pipes (acid-polymer liquid supplementary pipe 145, alkaline liquid supplementary pipe 146, and electroconductive-polymer liquid supplementary pipe 147), respectively.

In a second modification of the substrate processing apparatus 1 shown in FIG. 15, a neutral liquid and an electroconductive polymer liquid are discharged from the nozzles corresponding thereto, and land on the upper surface of the substrate W in the polymer-containing liquid supplying step (Step S4). The neutral liquid and the electroconductive polymer liquid are mixed together on the upper surface of the substrate W, and a polymer-containing liquid is formed.

FIG. 16 is a schematic view for describing a third modification of the wet processing unit 2W. Unlike the example of FIG. 3, the wet processing unit 2W may include a heating fluid nozzle 12 that supplies a heating fluid that heats the substrate W toward the lower surface of the substrate W held by the spin chuck 5, instead of the heater unit 6, as shown in FIG. 16.

The heating fluid nozzle 12 is inserted in, for example, the through-hole 21a of the spin base 21. A discharge port 12a of the heating fluid nozzle 12 faces the central region of the lower surface of the substrate W from below.

A heating fluid pipe 43 that guides a heating fluid to the heating fluid nozzle 12 is connected to the heating fluid nozzle 12. A heating fluid valve 53A that opens and closes a flow path in the heating fluid pipe 43 and a heating fluid flow-rate adjusting valve 53B that adjusts the flow rate of a heating fluid in the heating fluid pipe 43 are interposed in the heating fluid pipe 43. A heater 53C (temperature adjusting unit) that adjusts the temperature of a heating fluid supplied to the heating fluid nozzle 12 may be provided.

When the heating fluid valve 53A is opened, a heating fluid is discharged upwardly from the discharge port 12a of the heating fluid nozzle 12 in a continuous flow at a flow rate according to the opening degree of the heating fluid flow-rate adjusting valve 53B, and is supplied to the central region of the lower surface of the substrate W.

The heating fluid is supplied to the lower surface of the substrate W, and, as a result, the polymer film 101 on the upper surface of the substrate W is heated through the substrate W, thereby making it possible to facilitate the removal of the oxide layer by means of the polymer film 101 (removal facilitating step). Additionally, the heating fluid is supplied to the lower surface of the substrate W, thereby also making it possible to oxidize the to-be-processed layer and to form an oxide layer (oxide layer forming step).

The heating fluid discharged from the heating fluid nozzle 12 is, for example, high-temperature DIW whose temperature is higher than a normal temperature and whose temperature is lower than the boiling point of the solvent of the polymer-containing liquid. The heating fluid discharged from the heating fluid nozzle 12 is not limited to the high-temperature DIW, and may be a high-temperature gas, such as high-temperature inert gas or high-temperature air.

The inert gas is, for example, a nitrogen (N₂) gas. The inert gas is a gas that does not react to the to-be-processed layer and does not react to the oxide layer. The inert gas is not limited to the nitrogen gas, and may be a rare gas, such as argon (Ar) gas, or a mixed gas in which a nitrogen gas and a rare gas are mixed together. In other words, the inert gas may be a gas that includes at least either one of a nitrogen gas and a rare gas.

It is possible to perform the substrate processing shown in FIG. 5, and is also possible to perform the substrate processing shown in FIG. 10 by means of the substrate processing apparatus 1 including the wet processing unit 2W shown in FIG. 16. If the substrate processing shown in FIG. 10 is performed by the substrate processing apparatus 1 including the wet processing unit 2W shown in FIG. 12, the heating fluid nozzle 12 functions as a substrate oxidizing unit.

If the heating oxidation step (Step S10) is performed by use of the wet processing unit 2W shown in FIG. 16, it is preferable to adjust the temperature of a heating fluid so that the temperature of the heating fluid in the oxide layer forming step becomes higher than the temperature of the heating fluid in the removal facilitating step.

<Configuration of Substrate Processing Apparatus according to Second Preferred Embodiment>

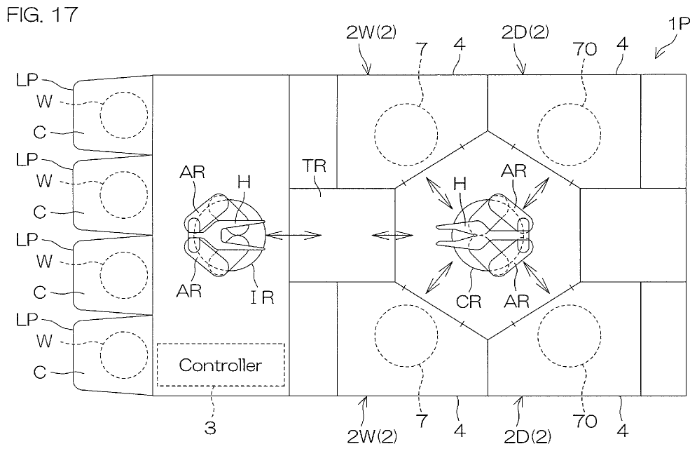

FIG. 17 is a plan view for describing a configuration of a substrate processing apparatus 1P according to a second preferred embodiment.

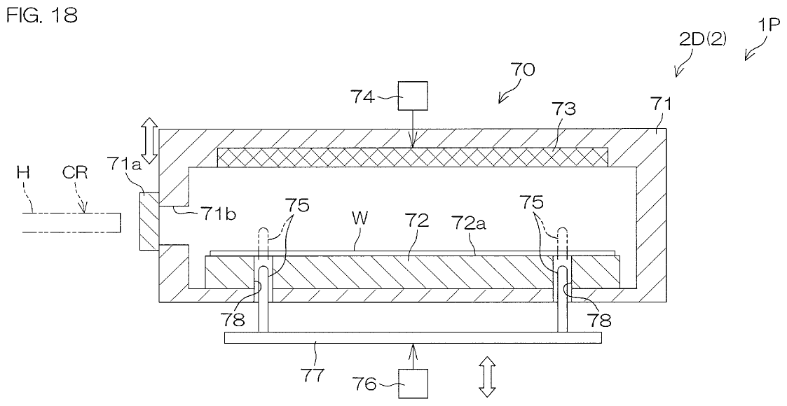

The substrate processing apparatus 1P according to the second preferred embodiment differs from the substrate processing apparatus 1 according to the first preferred embodiment (see FIG. 2A) mainly in that the processing unit 2 includes the wet processing unit 2W and a dry processing unit 2D. In FIG. 17, the same reference sign as in FIG. 1 to FIG. 16 mentioned above is assigned to a constituent equivalent to each constituent shown in FIG. 1 to FIG. 16, and a description of the constituent is omitted. The same applies to FIG. 18 to FIG. 21 described later.

In the example shown in FIG. 17, two processing towers on the transfer-robot-IR side include a plurality of wet processing units 2W, and two processing towers on the side opposite to the transfer robot IR include a plurality of dry processing units 2D. The configuration of the wet processing unit 2W according to the second preferred embodiment is the same as the configuration of the wet processing unit 2W (configuration shown in FIG. 3 or configuration shown in FIG. 12) according to the first preferred embodiment. In the wet processing unit 2W according to the second preferred embodiment, the oxidant nozzle 9 (see FIG. 3 and the like) can be omitted. The dry processing unit 2D includes a light irradiation processing unit 70 that is disposed in the chamber 4 and that applies light irradiation treatment to the substrate W.

A configuration example of the light irradiation treatment unit 70 will be hereinafter described. FIG. 18 is a schematic cross-sectional view for describing a configuration example of the light irradiation processing unit 70.

The light irradiation processing unit 70 includes a base 72 having a placing surface 72a on which the substrate W is placed, an optical processing chamber 71 that houses the base 72, a light irradiation unit 73 that irradiates light, such as ultraviolet light, toward the upper surface of the substrate W placed on the placing surface 72a, a plurality of lift pins 75 that pass through the base 72 and that move upwardly and downwardly, and a pin elevation driving mechanism 76 that moves the plurality of lift pins 75 in an up-down direction.

A carry-in/out opening 71b for the substrate W is provided in a sidewall of the optical processing chamber 71, and the optical processing chamber 71 has a gate valve 71a that opens and closes the carry-in/out opening 71b. When the carry-in/out opening 71b is opened, the hand H of the transfer robot CR can access the optical processing chamber 71. The substrate W is placed on the base 72, and, as a result, is horizontally held at a predetermined second holding position. The second holding position is a position of the substrate W shown in FIG. 18, and is a position at which the substrate W is held in a horizontal attitude.

The light irradiation unit 73 includes, for example, a plurality of light irradiation lamps. The light irradiation lamp is, for example, a xenon lamp, a mercury lamp, a heavy hydrogen lamp, or the like. The light irradiation unit 73 is configured to irradiate ultraviolet light of, for example, not less than 1 nm and not more than 400 nm, and, preferably, of not less than 1 nm and not more than 300 nm. In detail, an energizing unit 74, such as a power source, is connected to the light irradiation unit 73, and electric power is supplied from the energizing unit 74, and, as a result, the light irradiation unit 73 (a light irradiation lamp of the light irradiation unit 73) irradiates light. A to-be-processed layer of the substrate W is oxidized by light irradiation, and an oxide layer is formed.

The plurality of lift pins 75 are inserted in a plurality of through-holes 78, respectively, that pass through the base 72 and the optical processing chamber 71. The plurality of lift pins 75 are connected together by means of a connection plate 77. The pin elevation driving mechanism 76 raises and lowers the connection plate 77, and, as a result, the plurality of lift pins 75 are moved upwardly and downwardly between an upper position (position shown by an alternate long and two short dashed line in FIG. 18) at which the substrate W is supported at a position higher than the placing surface 72a and a lower position (position shown by a solid line in FIG. 18) at which a forward end portion (upper end portion) of the pin is immersed into a space lower than the placing surface 72a. The pin elevation driving mechanism 76 may be an electric motor or an air cylinder, or may be an actuator other than these devices.

<Example of Substrate Processing According to Second Preferred Embodiment>

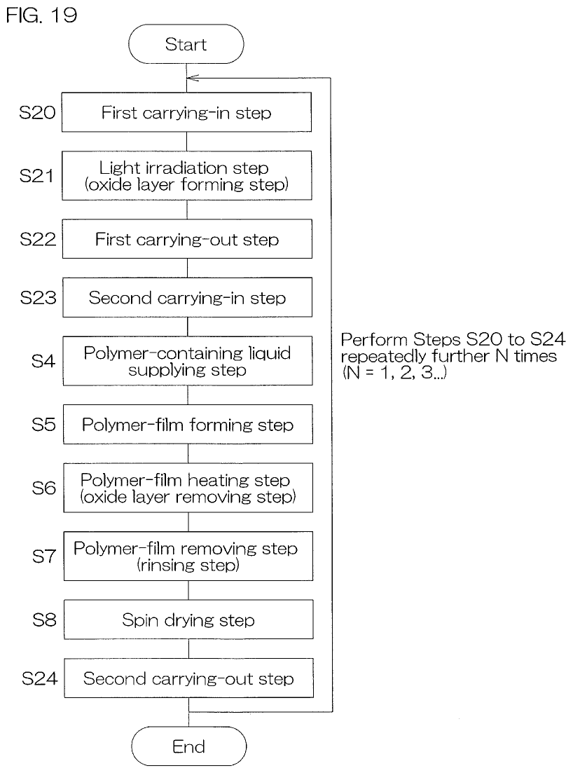

FIG. 19 is a flowchart for describing an example of substrate processing performed by the substrate processing apparatus 1P according to the second preferred embodiment. The substrate processing according to the second preferred embodiment differs from the substrate processing according to the first preferred embodiment (see FIG. 5) mainly in that the formation of the oxide layer is performed by the dry processing unit 2D, and the removal of the oxide layer is performed by the wet processing unit 2W.

A difference between the substrate processing according to the second preferred embodiment and the substrate processing according to the first preferred embodiment (see FIG. 5) will be hereinafter described in detail with reference mainly to FIG. 18 and FIG. 19.

First, a not-yet-processed substrate W is carried from the carrier C into the dry processing unit 2D by means of the transfer robots IR and CR (see FIG. 17), and is delivered to the plurality of lift pins 75 placed at the upper position (first carrying-in step: Step S20). The pin elevation driving mechanism 76 moves the plurality of lift pins 75 to the lower position, and, as a result, the substrate W is placed on the placing surface 72a. Thereby, the substrate W is horizontally held (first substrate holding step).

Thereafter, the transfer robot CR recedes outwardly from the dry processing unit 2D, and then a light irradiation step (Step S21) of irradiating light to the upper surface of the substrate W and forming an oxide layer is performed. In detail, the energizing unit 74 supplies electric power to the light irradiation unit 73. Thereby, light irradiation to the substrate W by means of the light irradiation unit 73 is started. The to-be-processed layer exposed from the upper surface of the substrate W is oxidized by the light irradiation, and an oxide layer is formed (oxide layer forming step, light irradiation step, dry oxidation step). The oxide layer formed by the light irradiation has a thickness of not less than 10 nm and not more than 20 nm. The light irradiation unit 73 functions as a substrate oxidizing unit.

Light irradiation is performed during a predetermined period of time, and then the transfer robot CR enters the dry processing unit 2D, and receives the substrate W, which has been oxidized, from the base 72, and carries the substrate W out of the dry processing unit 2D (first carrying-out step: Step S22). In detail, the pin elevation driving mechanism 76 moves the plurality of lift pins 75 to the upper position, and the plurality of lift pins 75 lift the substrate W from the base 72. The transfer robot CR receives the substrate W from the plurality of lift pins 75.

The substrate W carried out of the dry processing unit 2D is carried into the wet processing unit 2W by means of the transfer robot CR, and is delivered to the plurality of chuck pins 20 of the spin chuck 5 (second carrying-in step: Step S23). The opening-closing unit 25 moves the plurality of chuck pins 20 to the closed position, and, as a result, the substrate W is gripped by the plurality of chuck pins 20. Thereby, the substrate W is horizontally held by the spin chuck 5 (second substrate holding step). The spin motor 23 starts the rotation of the substrate W in a state in which the substrate W is being held by the spin chuck 5 (substrate rotating step).

Thereafter, the polymer-containing liquid supplying step (Step S4), the polymer-film forming step (Step S5), the polymer-film heating step (Step S6), and the polymer-film removing step (Step S7) are performed as shown in FIG. 6C to FIG. 6G.

After the polymer-film removing step is completed, the spin drying step (Step S8) is performed. In detail, the rinsing-liquid valve 52A is closed, and the supply of the rinsing liquid to the upper surface of the substrate W is stopped. Thereafter, the spin motor 23 accelerates the rotation of the substrate W, and rotates the substrate W at a high speed. The substrate W is rotated at a drying speed of, for example, 1500 rpm. As a result, a great centrifugal force acts on a rinsing liquid on the substrate W, and the rinsing liquid on the substrate W is shaken off to an area around the substrate W.

Thereafter, the spin motor 23 stops the rotation of the substrate W. The transfer robot CR enters the wet processing unit 2W, and receives the substrate W from the plurality of chuck pins 20, and carries the substrate W out of the wet processing unit 2W (second carrying-out step: Step S24).

Thereafter, cycle processing in which the steps ranging from the first carrying-in step (Step S20) to the second carrying-out step (Step S24) are set as one cycle is further performed once or more. In other words, the cycle processing is performed a plurality of cycles. After the last second carrying-out step (Step S24) is completed, the substrate W is delivered from the transfer robot CR to the transfer robot IR, and is housed in the carrier C by means of the transfer robot IR.

According to the second preferred embodiment, the formation of the oxide layer 103 and the removal of the oxide layer 103 are alternately repeated in the same way as in the first preferred embodiment, and therefore it is possible to accurately etch the to-be-processed layer 102. Additionally, according to the second preferred embodiment, the substrate W is etched by the acid polymer contained in the polymer film 101 formed on the upper surface of the substrate W. Therefore, it is possible to make a substance (hydrofluoric acid or acid polymer) required to etch the to-be-processed layer 102 small in amount used.

The following effects are further fulfilled according to the second preferred embodiment. For example, according to the second preferred embodiment, the to-be-processed layer 102 is oxidized by light irradiation. In other words, it is possible to oxidize the substrate W without using a liquid oxidant. Therefore, it is possible to save labor hours for removing a liquid oxidant adhering to the upper surface of the substrate W. Additionally, a configuration is formed to oxidize the substrate W by light irradiation, thereby making it possible to etch the to-be-processed layer 102 without using an oxidant. In other words, it is possible to make a substance required to etch the to-be-processed layer 102 small in amount used.

Unlike the substrate processing shown in FIG. 19, spin drying steps other than the last spin drying step (Step S8) may be excluded. In detail, the substrate W may be transferred from the wet processing unit 2W to the dry processing unit 2D without performing a spin drying step after the polymer-film removing step is completed, except after the last polymer-film removing step (Step S7) is completed.

<Modification of Dry Processing Unit>

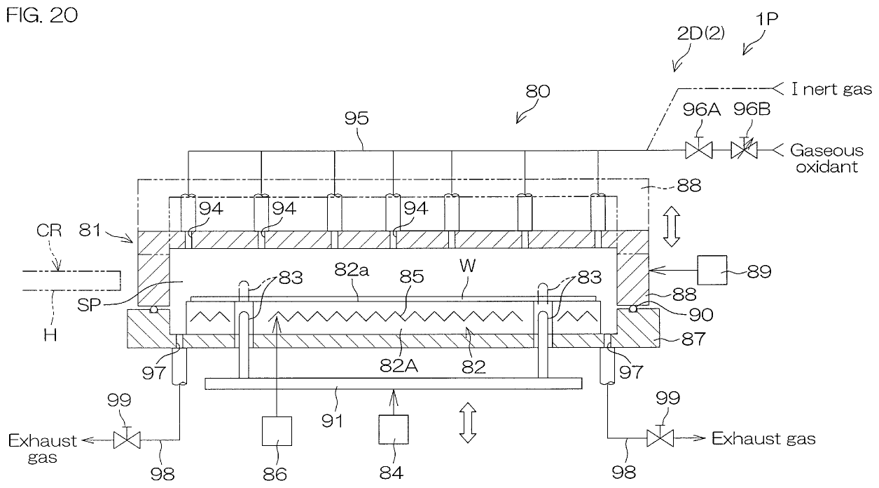

The dry processing unit 2D may include a heat treatment unit 80 instead of the light irradiation processing unit 70. FIG. 20 is a schematic cross-sectional view for describing a configuration example of the heat treatment unit 80.

The heat treatment unit 80 includes a heater unit 82 having a heating surface 82a on which the substrate W is placed and a heat treatment chamber 81 that houses the heater unit 82.

The heater unit 82 has the form of a disk-shaped hot plate. The heater unit 82 includes a plate body 82A and a heater 85. An upper surface of the plate body 82A forms the heating surface 82a. The heater 85 may be a resistive element built into the plate body 82A. The heater 85 is capable of heating the substrate W to a temperature substantially equal to the temperature of the heater 85. The heater 85 is configured to heat the substrate W placed on the heating surface 82a in a predetermined temperature range of not less than a normal temperature and not more than 400° C. In detail, an energizing unit 86, such as a power source, is connected to the heater 85, and an electric current supplied from the energizing unit 86 is adjusted, and, as a result, the temperature of the heater 85 is changed to a temperature in the predetermined temperature range.

The heat treatment chamber 81 includes a chamber body 87 that is upwardly open and a lid 88 that moves upwardly and downwardly above the chamber body 87 and with which an opening of the chamber body 87 is sealed. The heat treatment unit 80 is provided with a lid elevation driving mechanism 89 that elevates the lid 88 (i.e., that moves the lid 88 in the up-down direction). A space between the chamber body 87 and the lid 88 is sealed up by means of an elastic member 90, such as an O ring.

The lid 88 is upwardly and downwardly moved by the lid elevation driving mechanism 89 between a lower position (position shown by a solid line in FIG. 20) at which a sealed processing space SP is formed within the chamber body 87 by closing the opening of the chamber body 87 and an upper position (position shown by an alternate long and two short dashed line in FIG. 20) to which the lid 88 upwardly recedes so as to open the opening. The sealed processing space SP is a space contiguous to the upper surface of the substrate W. The hand H of the transfer robot CR is accessible to the inside of the heat treatment chamber 81 when the lid 88 is placed at the upper position. The lid elevation driving mechanism 89 may be an electric motor or an air cylinder, or may be an actuator other than these devices.

The heat treatment unit 80 additionally includes of a plurality of lift pins 83 that pass through the plate body 82A and that move upwardly and downwardly and a pin elevation driving mechanism 84 that moves the plurality of lift pins 83 in the up-down direction. The plurality of lift pins 83 are connected together by means of a connection plate 91. The pin elevation driving mechanism 84 raises and lowers the connection plate 91, and, as a result, the plurality of lift pins 83 are moved upwardly and downwardly between the upper position (position shown by the alternate long and two short dashed line in FIG. 20) at which the substrate W is supported at a higher position than the heating surface 82a and the lower position (position shown by the solid line in FIG. 20) at which the forward end portion (upper end portion) of the pin is immersed into a space lower than the heating surface 82a. The pin elevation driving mechanism 84 may be an electric motor or an air cylinder, or may be an actuator other than these devices.

The plurality of lift pins 83 are inserted in a plurality of through-holes, respectively, that pass through the heater unit 82 and the chamber body 87. A fluid may be prevented from entering the through-hole from outside the heat treatment chamber 81 by means of, for example, bellows (not shown) that surround the lift pins 83.

The heat treatment unit 80 is provided with a plurality of gas introducing ports 94 that introduce a gaseous oxidant into the sealed processing space SP formed in the heat treatment chamber 81. Each of the gas introducing ports 94 is a through-hole that passes through the lid 88.

The gaseous oxidant is a gas that oxidizes the to-be-processed layer exposed from the substrate W and, as a result, forms an oxide layer. For example, the gaseous oxidant is an ozone (O₃) gas. The gaseous oxidant may be, for example, an oxidative water vapor, a superheated water vapor, or the like without being limited to the ozone gas.

A gaseous oxidant pipe 95 that supplies a gaseous oxidant to the gas introducing port 94 is connected to the plurality of gas introducing ports 94. The gaseous oxidant pipe 95 branches off on the way from a gaseous oxidant supply source (not shown) toward the plurality of gas introducing ports 94. A gaseous oxidant valve 96A that opens and closes a flow path of the gaseous oxidant pipe 95 and a gaseous oxidant flow-rate adjusting valve 96B that adjusts the flow rate of the gaseous oxidant in the gaseous oxidant pipe 95 are interposed in the gaseous oxidant pipe 95.

When the gaseous oxidant valve 96A is opened, the gaseous oxidant is introduced into the sealed processing space SP from the plurality of gas introducing ports 94, and the gaseous oxidant is supplied toward the upper surface of the substrate W.

The plurality of gas introducing ports 94 may be configured to be able to supply an inert gas in addition to the gaseous oxidant (see the alternate long and two short dashed line of FIG. 20). Additionally, the inert gas can be mixed with the gaseous oxidant introduced into the sealed processing space SP, and the concentration (partial pressure) of an oxidant can be adjusted by the mixing degree of the inert gas.

The heat treatment unit 80 is provided with a plurality of discharge ports 97 that are formed in the chamber body 87 and that discharge an internal atmosphere of the heat treatment chamber 81. A discharge pipe 98 is connected to each of the discharge ports 97, and a discharge valve 99 that opens and closes a flow path of the discharge pipe 98 is interposed in the discharge pipe 98.

<Another Example of Substrate Processing according to Second Preferred Embodiment>

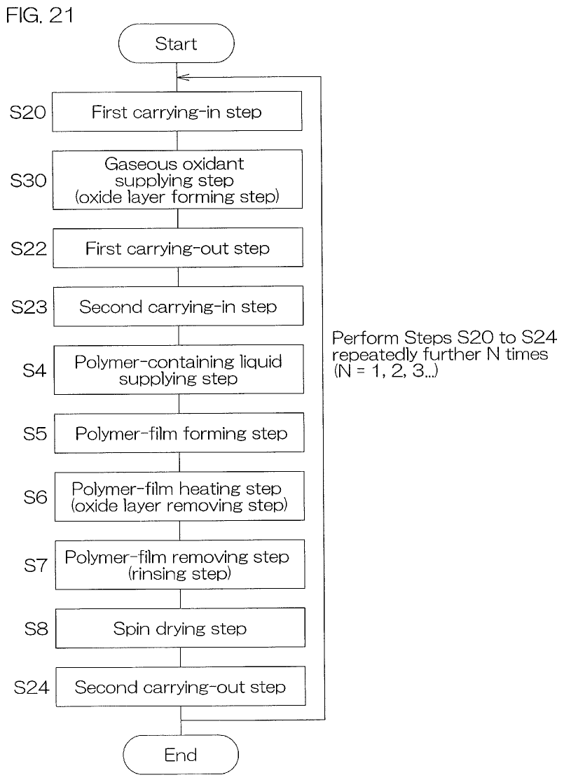

FIG. 21 is a flowchart for describing another example of substrate processing according to the second preferred embodiment. The substrate processing shown in FIG. 21 differs from the substrate processing shown in FIG. 19 in that a gaseous oxidant supplying step (Step S30) of supplying a gaseous oxidant toward the upper surface of the substrate W while heating the substrate W and, as a result, forming an oxide layer is performed instead of the light irradiation step (Step S21).

Referring mainly to FIG. 20 and FIG. 21, the substrate processing shown in FIG. 21 will be hereinafter described centering on a difference from the substrate processing shown in FIG. 19.

First, a not-yet-processed substrate W is carried from the carrier C into the dry processing unit 2D by means of the transfer robots IR and CR (also see FIG. 17) (first carrying-in step: Step S20). The pin elevation driving mechanism 84 moves the plurality of lift pins 83 to the lower position, and, as a result, the substrate W is placed on the heating surface 82a. Thereby, the substrate W is horizontally held (first substrate holding step).

Thereafter, the lid 88 is lowered, and, as a result, a state is reached in which the substrate W is placed on the heating surface 82a of the heater unit 82 in the sealed processing space SP formed by both the chamber body 87 and the lid 88. The substrate W placed on the heating surface 82a is heated to a predetermined oxidizing temperature by means of the heater unit 82 (substrate heating step, heater heating step). The predetermined oxidizing temperature is, for example, not less than 100° C. and not more than 400° C.

The gaseous oxidant valve 96A is opened in a state in which the sealed processing space SP is formed. Thereby, a gaseous oxidant, such as ozone gas, is introduced from the plurality of gas introducing ports 94 into the sealed processing space SP, and the gaseous oxidant is supplied toward a space above the substrate W (gaseous oxidant supplying step: Step S30).

An inert gas may be supplied from the gas introducing port 94 to the sealed processing space SP, and the atmosphere in the sealed processing space SP may be replaced by the inert gas before the gaseous oxidant is supplied into the sealed processing space SP (preliminary replacing step).

The to-be-processed layer exposed from the substrate W is oxidized, and an oxide layer is formed by means of the gaseous oxidant discharged from the plurality of gas introducing ports 94 (oxide layer forming step, gaseous oxidant supplying step, dry oxidation step). The oxide layer formed by the gaseous oxidant, such as ozone gas, has a thickness of, for example, not less than 10 nm and not more than 20 nm. The substrate W is heated to an oxidizing temperature on the heater unit 82. Therefore, the heating oxidation step of supplying a gaseous oxidant toward the upper surface of the substrate W while heating the substrate W at the oxidizing temperature is performed in the oxide layer forming step. As thus described, the gas introducing port 94 and the heater unit 82 function as a substrate oxidizing unit.

The discharge valve 99 is opened while the gaseous oxidant is being supplied. Therefore, the gaseous oxidant in the sealed processing space SP is discharged from the discharge pipe 98.

The upper surface of the substrate W is processed by the gaseous oxidant, and then the gaseous oxidant valve 96A is closed. Thereby, the supply of the gaseous oxidant to the sealed processing space SP is stopped. Thereafter, the lid 88 is moved to the upper position. The lid 88 may be moved to the upper position after replacing the atmosphere in the sealed processing space SP with an inert gas.

After heat treatment is performed during a fixed period of time, the transfer robot CR enters the dry processing unit 2D, and the substrate W that has been oxidized is carried out of the dry processing unit 2D (first carrying-out step: Step S22). In detail, the pin elevation driving mechanism 84 moves the plurality of lift pins 83 to the upper position, and the plurality of lift pins 83 lift the substrate W from the heater unit 82. The transfer robot CR receives the substrate W from the plurality of lift pins 83. The substrate W carried out of the dry processing unit 2D is carried into the wet processing unit 2W by means of the transfer robot CR, and is delivered to the plurality of chuck pins 20 of the spin chuck 5 (second carrying-in step: Step S23).

Thereafter, the steps of from the polymer-containing liquid supplying step (Step S4) to the second carrying-out step (Step S24) are performed. Thereafter, cycle processing in which the steps of from the first carrying-in step (Step S20) to the second carrying-out step (Step S24) are set as one cycle is further performed once or more. In other words, cycle processing is performed a plurality of cycles.

Likewise, in the other example of the substrate processing of the second preferred embodiment shown in FIG. 21, it is possible to form the oxide layer 103 without using a liquid oxidant. Therefore, it is possible to save labor hours for removing a liquid oxidant adhering to the upper surface of the substrate W.

The oxide layer 103 may be formed by only either one of the supply of a gaseous oxidant or the heating of the substrate W by use of the dry processing unit 2D shown in FIG. 20. Additionally, the dry processing unit 2D shown in FIG. 18 and the dry processing unit 2D shown in FIG. 20 may be combined together. For example, the oxide layer 103 may be formed by heating the substrate W while irradiating light to a substrate W on which the oxide layer 103 may be formed. In detail, the substrate W is heated while irradiating ultraviolet light to the substrate W, and, as a result, it is possible to perform ultraviolet radical oxidation treatment. Additionally, the oxide layer 103 may be formed by supplying a gaseous oxidant to the substrate W while irradiating light to the substrate W.

In other words, not only the dry processing units shown in FIG. 18 and FIG. 20 but also a dry processing unit that is capable of forming the oxide layer 103 by at least any one among the irradiation of light, the supply of a gaseous oxidant, and the heating of the substrate W is employable as the dry processing unit 2D.

<Configuration of Substrate Processing Apparatus According to Third Preferred Embodiment>

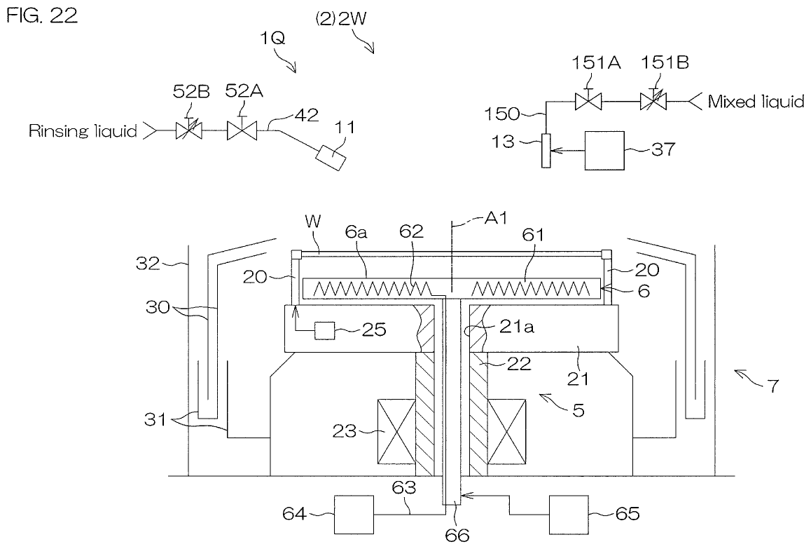

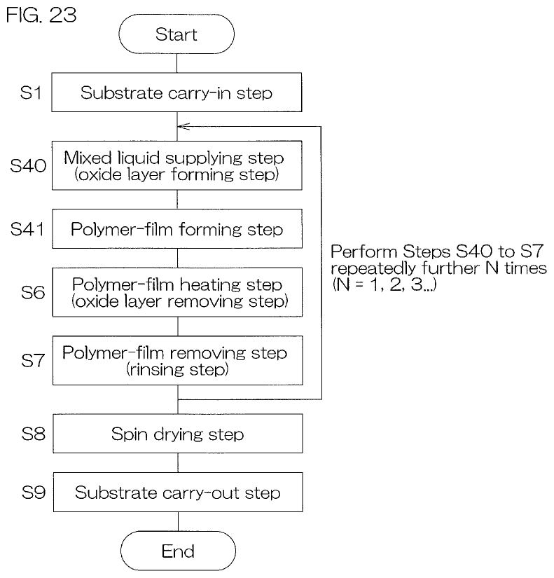

FIG. 22 is a schematic cross-sectional view for describing a configuration example of a wet processing unit 2W included in a substrate processing apparatus 1Q according to a third preferred embodiment. In FIG. 22, the same reference sign as in FIG. 1 to FIG. 21 mentioned above is assigned to a constituent equivalent to each constituent shown in FIG. 1 to FIG. 21, and a description of the constituent is omitted. The same applies to FIG. 23A to FIG. 26 described later.

The substrate processing apparatus 1Q according to the third preferred embodiment differs from the substrate processing apparatus 1 according to the first preferred embodiment mainly in that the wet processing unit 2W includes a mixed liquid nozzle 13 that discharges a mixed liquid of a liquid oxidant and a polymer-containing liquid instead of the oxidant nozzle 9 and the polymer-containing liquid nozzle 10.

The mixed liquid contains an oxidant, an acid polymer, an alkaline component, and an electroconductive polymer, each of which serves as a solute, and a solvent that dissolves the solute. The same components as the oxidant, the acid polymer, the alkaline component, and the electroconductive polymer of the first preferred embodiment can be used as the oxidant, the acid polymer, the alkaline component, and the electroconductive polymer contained in the mixed liquid, respectively. The solvent contained in the mixed liquid is merely required to be a liquid at a normal temperature, to be capable of dissolving or swelling the acid polymer and the electroconductive polymer, to be capable of dissolving the oxidant and the alkaline component, and to be a substance that is evaporated by rotating or heating a substrate W. In detail, the same solvent as the solvent contained in the polymer-containing liquid can be used.

The mixed liquid nozzle 13 is a movable nozzle that is movable at least in the horizontal direction. The mixed liquid nozzle 13 is moved in the horizontal direction by means of a third nozzle moving unit 37 having the same configuration as the first nozzle moving unit 35. The mixed liquid nozzle 13 may be movable in the vertical direction. The mixed liquid nozzle 13 may be a stationary nozzle whose horizontal and vertical positions are fixed unlike the preferred embodiment.

A mixed liquid pipe 150 that guides a mixed liquid to the mixed liquid nozzle 13 is connected to the mixed liquid nozzle 13. A mixed liquid valve 151A that opens and closes a flow path in the mixed liquid pipe 150 and a mixed liquid flow-rate adjusting valve 151B that adjusts the flow rate of a mixed liquid flowing through the flow path in the mixed liquid pipe 150 are interposed in the mixed liquid pipe 150.

<Example of Substrate Processing According to Third Preferred Embodiment>

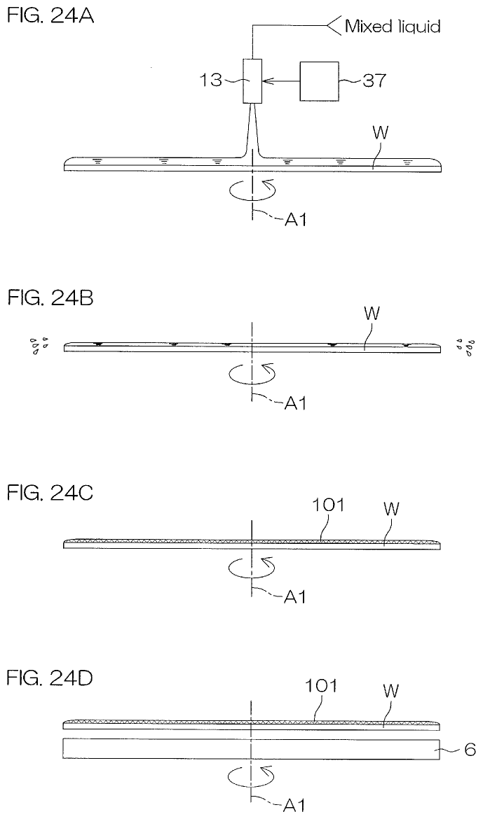

FIG. 23 is a flowchart for describing an example of substrate processing performed by the substrate processing apparatus 1Q according to the third preferred embodiment. FIG. 24A to FIG. 24C are schematic views each of which is for describing an aspect of a substrate W when an example of the substrate processing according to the third preferred embodiment is performed. The substrate processing according to the third preferred embodiment differs from the substrate processing according to first preferred embodiment (see FIG. 5) mainly in that the oxide layer 103 (see FIG. 1) is formed by the supply of a mixed liquid to a substrate W and in that the oxide layer 103 is removed by the polymer film 101 formed from a mixed liquid.

Referring mainly to FIG. 22 and FIG. 23, the substrate processing performed by the substrate processing apparatus 1Q will be hereinafter described centering on a difference from the substrate processing according to the first preferred embodiment. Reference is made to FIG. 24A to FIG. 24C where appropriate.

A not-yet-processed substrate W is carried into the wet processing unit 2W, and then a mixed liquid supplying step (Step S40) of supplying a mixed liquid to the upper surface of the substrate W is performed. In detail, the third nozzle moving unit 37 moves the mixed liquid nozzle 13 to the processing position. The processing position of the mixed liquid nozzle 13 is, for example, a center position. The mixed liquid nozzle 13 faces a central region of the upper surface of the substrate W when the mixed liquid nozzle 13 is placed at the center position.

The mixed liquid valve 151A is opened in a state in which the mixed liquid nozzle 13 is placed at the processing position. Thereby, the liquid oxidant and the polymer-containing liquid are mixed together in the mixed liquid pipe 150, and a mixed liquid is formed (mixed liquid forming step). The mixed liquid is supplied (discharged) from the mixed liquid nozzle 13 toward the central region of the upper surface of the substrate W as shown in FIG. 24A (mixed liquid supplying step, mixed liquid discharging step, nozzle supplying step). The mixed liquid discharged from the mixed liquid nozzle 13 lands on the central region of the upper surface of the substrate W.

The mixed liquid that has landed on the upper surface of the substrate W is spread by a centrifugal force caused by the rotation of the substrate W toward the peripheral edge portion of the upper surface of the substrate W. Thereby, the whole area of the upper surface of the substrate W is covered with the mixed liquid. The to-be-processed layer 102 exposed from the upper surface of the substrate W is oxidized by an oxidant contained in the mixed liquid (oxide layer forming step, mixed liquid oxidation step). Thus, the mixed liquid nozzle 13 functions as a substrate oxidizing unit.

Thereafter, a polymer-film forming step (Step S41) of forming a solid or semisolid polymer film 101 (see FIG. 24C) on the upper surface of the substrate W by evaporating at least a portion of a solvent contained in the mixed liquid on the upper surface of the substrate W is performed as shown in FIG. 24B and FIG. 24C.

In detail, the mixed liquid valve 151A is closed, and the discharge of the mixed liquid from the mixed liquid nozzle 13 is stopped. The mixed liquid valve 151A is closed, and then the mixed liquid nozzle 13 is moved to the retreat position by means of the third nozzle moving unit 37. When the mixed liquid nozzle 13 is placed at the retreat position, the mixed liquid nozzle 13 does not face the upper surface of the substrate W, and is placed outside the processing cup 7 in a plan view.

The mixed liquid valve 151A is closed, and then the rotation of the substrate W is accelerated so that the rotation speed of the substrate W reaches a predetermined spin-off speed as shown in FIG. 24B (rotation accelerating step). The spin-off speed is, for example, 1500 rpm. The rotation of the substrate W at the spin-off speed is continued for, for example, 30 seconds. A portion of the mixed liquid on the substrate W is scattered from the peripheral edge portion of the substrate W to an area outside the substrate W by a centrifugal force caused by the rotation of the substrate W, and a liquid film of the mixed liquid on the substrate W is thinned (spin-off step).

An airflow in which a gas contiguous to the mixed liquid on the substrate W flows from the central side to the peripheral edge side of the upper surface of the substrate W is formed by the action of a centrifugal force caused by the rotation of the substrate W. This airflow excludes a gaseous solvent contiguous to the mixed liquid on the substrate W from an atmosphere contiguous to the substrate W. Therefore, the evaporation (volatilization) of the solvent from the polymer-containing liquid on the substrate W is facilitated, and a solid or semisolid polymer film 101 is formed as shown in FIG. 24C (polymer-film forming step). As thus described, the mixed liquid nozzle 13 and the spin motor 23 function as a polymer-film forming unit.

The polymer film 101 is higher in viscosity than the mixed liquid, and therefore the polymer film 101 stays on the substrate W without being completely excluded from on the substrate W despite the fact that the substrate W is rotating. Immediately after the polymer film 101 is formed, an alkaline component is contained in the polymer film 101, and therefore the acid polymer contained in the polymer film 101 is in a substantially deactivated state. Therefore, the removal of the oxide layer is hardly performed.

It should be noted that an oxidant, such as ozone or hydrogen peroxide, is ordinarily in a liquid state or in a gaseous state at a normal temperature, and therefore most of the oxidant is removed from on the substrate W through the spin-off step without being changed to be semisolid or solid in response to the evaporation of the solvent like the acid polymer. Therefore, the oxidant remaining on the substrate W is slight in amount. Therefore, the possibility that a to-be-processed layer 102 newly exposed after the removal of the oxide layer by means of the polymer film 101 will be oxidized by the oxidant remaining on the substrate W is substantially negligible.

Thereafter, the polymer-film heating step (Step S6) of heating the polymer film 101 on the substrate W is performed. In detail, the heater unit 6 is placed at the proximal position, and the substrate W is heated as shown in FIG. 24D (substrate heating step, heater heating step).

The polymer film 101 formed on the substrate W through the substrate W is heated. The polymer film 101 is heated, and, as a result, the alkaline component is evaporated, and the acid polymer regains activity (alkali component evaporating step, alkali component removing step) Therefore, the etching of the substrate W is started by the action of the acid polymer contained in the polymer film 101 (etching starting step, etching step).

In detail, the removal of the oxide layer formed at the surface layer portion of the upper surface of the substrate W is started (oxide layer removal starting step, oxide layer removing step). The acid polymer is neutralized by the alkaline component, and is in a substantially deactivated state until the polymer film 101 is heated after the polymer film 101 is formed. Therefore, the etching of the substrate W is not started until the polymer film 101 is heated after the polymer film 101 is formed.

Thereafter, the polymer-film removing step (Step S7) is performed as shown in FIG. 6G. The first polymer-film removing step is completed, and then cycle processing in which the steps of from the mixed liquid supplying step (Step S40) to the polymer-film removing step (Step S7) are set as one cycle is further performed once or more. In other words, the cycle processing is performed a plurality of cycles. The last polymer-film removing step (Step S7) is completed, and then the spin drying step (Step S8) and the substrate carry-out step (Step S9) are performed.

According to the third preferred embodiment, the formation of the oxide layer 103 and the removal of the oxide layer 103 are alternately repeated in the same way as in the first preferred embodiment, thereby making it possible to accurately etch the to-be-processed layer 102. Additionally, according to the third preferred embodiment, the oxide layer 103 is removed by the acid polymer contained in the polymer film 101 formed on the upper surface of the substrate W. Therefore, it is possible to make a substance (hydrofluoric acid or acid polymer) required to etch the to-be-processed layer 102 small in amount used.

According to the third preferred embodiment, the following effect is additionally fulfilled. For example, according to the third preferred embodiment, the oxide layer 103 is formed by an oxidant contained in the mixed liquid. Thereafter, the oxide layer 103 is removed by an acid polymer contained in the polymer film 101 formed by evaporating a solvent contained in the mixed liquid on the substrate W. In other words, the mixed liquid is supplied to the upper surface of the substrate W, and the polymer film 101 is formed from the mixed liquid on the upper surface of the substrate W, and, as a result, the formation and the removal of the oxide layer 103 are successively performed. Therefore, it is possible to make a substance for use in the etching of the to-be-processed layer 102 smaller in amount used than in a case in which a continuously-flowing liquid is used for each of the formation and the removal of the oxide layer 103.

<Mixed-Liquid Supplying Method According to Third Preferred Embodiment>

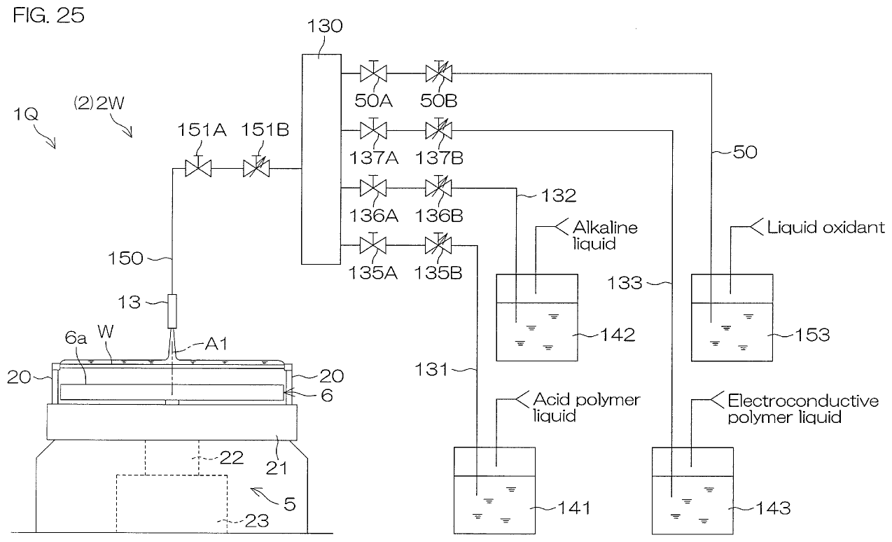

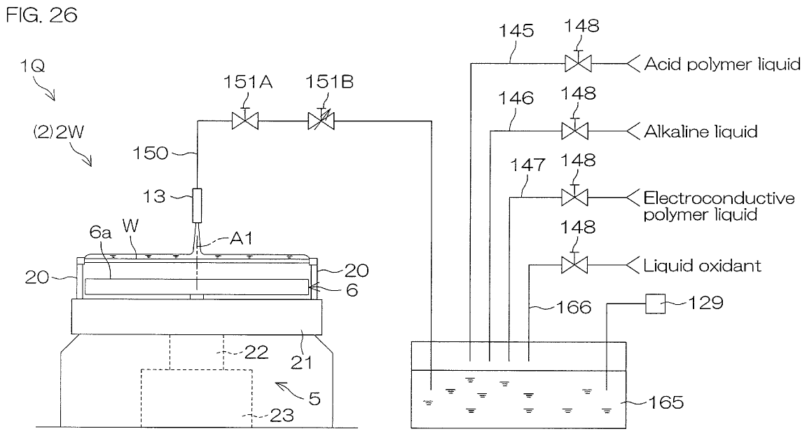

FIG. 25 and FIG. 26 are schematic views for describing a first example and a second example, respectively, of a method of supplying a mixed liquid to a substrate W.

In the first example of the method of supplying a mixed liquid shown in FIG. 25, an acid polymer liquid, an alkaline liquid, an electroconductive polymer liquid, and a liquid oxidant are mixed together in the mixing pipe 130, and, as a result, a mixed liquid is formed, and the mixed liquid formed in the mixing pipe 130 is discharged from the mixed liquid nozzle 13, and is supplied to the upper surface of the substrate W (mixed liquid supplying step).

The mixing pipe 130 is connected to the mixed liquid pipe 150. A liquid oxidant is supplied from an oxidant tank 153 to the mixing pipe 130 through the oxidant pipe 40. An acid polymer liquid is supplied from the acid-polymer liquid tank 141 to the mixing pipe 130 through the acid-polymer liquid pipe 131. An alkaline liquid is supplied from the alkaline liquid tank 142 to the mixing pipe 130 through the alkaline liquid pipe 132. An electroconductive polymer liquid is supplied from the electroconductive-polymer liquid tank 143 to the mixing pipe 130 through the electroconductive-polymer liquid pipe 133.

It is possible to adjust the percentage (concentration) of each component contained in the mixed liquid discharged from the discharge port of the mixed liquid nozzle 13 by adjusting the opening degree of at least one of the supply flow-rate adjusting valves (acid-polymer liquid flow-rate adjusting valve 135B, alkaline liquid flow-rate adjusting valve 136B, electroconductive-polymer liquid flow-rate adjusting valve 137B, and oxidant supply flow-rate adjusting valve 155B).

If this supply method is employed, a liquid oxidant and polymer-containing liquids (acid polymer liquid, alkaline liquid, and electroconductive polymer liquid) are mixed together in the pipe (mixing pipe 130) connected to the mixed liquid nozzle 13, and, as a result, a mixed liquid is formed. Therefore, the mixed liquid is formed immediately before the acid polymer liquid, the alkaline liquid, the electroconductive polymer liquid, and the liquid oxidant are supplied to the upper surface of the substrate W. Therefore, even if an oxidant and an acid polymer chemically react with each other, it is possible to make a substance for use in the etching of the to-be-processed layer 102 small in amount used while restraining a chemical change in both the oxidant and the acid polymer.

In the second example of the method of supplying a mixed liquid shown in FIG. 26, a liquid oxidant, an acid polymer liquid, an alkaline liquid, and an electroconductive polymer liquid are mixed together in a mixed liquid tank 165, and, as a result, a mixed liquid is formed. In the example shown in FIG. 26, a liquid oxidant, an acid polymer liquid, an alkaline liquid, and an electroconductive polymer liquid are supplied to the mixed liquid tank 165, and a mixed liquid is formed in the mixed liquid tank 165, and yet the mixed liquid may be formed by supplying a liquid oxidant and polymer-containing liquids (acid polymer liquid, alkaline liquid, and electroconductive polymer liquid) to the mixed liquid tank 165. In the wet processing unit 2W shown in FIG. 26, an opposite end of the mixed liquid pipe 150 is connected to the mixed liquid tank 165. An oxidant supplementary pipe 166, the acid-polymer liquid supplementary pipe 145, the alkaline liquid supplementary pipe 146, and the electroconductive-polymer liquid supplementary pipe 147 that supplementarily supply a liquid oxidant, an acid polymer liquid, an alkaline liquid, and an electroconductive polymer liquid, respectively, to the mixed liquid tank 165 are connected to the mixed liquid tank 165.

The liquid oxidant, the acid polymer liquid, the alkaline liquid, and the electroconductive polymer liquid are mixed together in the mixed liquid tank 165 that supplies a mixed liquid to the mixed liquid pipe 150, and, as a result, a mixed liquid is formed. Therefore, it is possible to make a substance for use in the etching of the to-be-processed layer 102 smaller in amount used while simplifying its equipment than in a configuration in which each liquid is supplied from mutually-different tanks to the mixed liquid nozzle 13.

### Other Preferred Embodiments

The present invention is not limited to the preferred embodiments described above but can further be implemented in other modes.

In the preferred embodiments described above, an acid polymer, an alkaline component, and an electroconductive polymer are each contained in a polymer-containing liquid as a solute. However, the alkaline component and the electroconductive polymer are not necessarily required to be contained in the polymer-containing liquid. Only either one of the alkaline component and the electroconductive polymer, in addition to the acid polymer, may be contained in the polymer-containing liquid as a solute.

Additionally, there is a case in which each constituent is schematically shown in a block, and yet the shape, the size, and the positional relationship of each block do not show the shape, the size, and the positional relationship of each constituent.

Additionally, the spin chuck 5 is not limited to a gripping-type chuck, and may be, for example, a vacuum-suction-type vacuum chuck. The vacuum chuck holds the substrate W in a horizontal attitude at the holding position by vacuum-sucking the rear surface of the substrate W, and rotates around a vertical rotational axis in that state, and, as a result, rotates the substrate W held by the spin chuck 5.

Additionally, in the preferred embodiments described above, the polymer-containing liquid or the mixed liquid is supplied to the upper surface of the substrate W, and then the solvent is evaporated from these liquids, and, as a result, the polymer film 101 is formed on the upper surface of the substrate W. However, unlike the preferred embodiments described above, the polymer film 101 may be formed on the upper surface of the substrate W by applying the semisolid polymer film 101 to the upper surface of the substrate W.

Additionally, in the polymer film heating step (Step S6) of each of the preferred embodiments described above, the polymer film 101 may be heated in a state in which an atmosphere contiguous to the substrate W has been replaced with an inert gas, such as nitrogen gas. This makes it possible to prevent an unintended oxide layer from being formed after the oxide layer 103 is removed.

Additionally, in the preferred embodiments described above, substrate processing including the oxide layer forming step and the oxide layer removing step is applied to the upper surface of the substrate W. However, substrate processing may be applied to the lower surface of the substrate W unlike the preferred embodiments described above.

Additionally, the surface layer portion of the major surface of the substrate W for use in the substrate processing according to the preferred embodiments described above is not required to have the structure shown in FIG. 1. For example, the to-be-processed layer 102 may be exposed from the entirety of the major surface of the substrate W, and the concavo-convex pattern 120 is not necessarily required to be formed. Additionally, the to-be-processed layer 102 is not required to be a metal layer, and may be a silicon oxide layer. Additionally, the to-be-processed layer 102 is not required to be made of a single substance, and may be made of a plurality of substances.

Additionally, the supply of a liquid oxidant from the oxidant nozzle 9 and the supply of a polymer-containing liquid from the polymer-containing liquid nozzle 10 are simultaneously performed by use of the wet processing unit 2W according to the first preferred embodiment, and, as a result, it also become possible to form a mixed liquid on the upper surface of the substrate W.

Additionally, the polymer-film heating step (Step S6) may be excluded in the substrate processing according to each of the preferred embodiments described above. Still additionally, the oxidant removing step (Step S3) may be excluded in the substrate processing (see FIG. 5) according to the first preferred embodiment described above. A spin drying step of rotating the substrate W at a high speed and shaking off a rinsing liquid serving as an oxidant removing liquid from the substrate W (not shown) may be performed between the oxidant removing step (Step S3) and the polymer-containing liquid supplying step (Step S4).

Additionally, pipes, pumps, valves, nozzle moving units, etc., are partly omitted and are not partly shown in each of the preferred embodiments described above, and yet this does not denote that these members do not exist, and, in practice, these members are provided at appropriate positions.

It should be noted that the terms “along,” “horizontal,” and “vertical” have been used in the preferred embodiments described above, and yet these are not required to be precisely “along,” precisely “horizontal,” and precisely “vertical.” In other words, these terms permit an error in manufacturing accuracy, installing accuracy, etc.

While the preferred embodiments of the present invention have been described in detail, these are merely specific examples used to clarify the technical content of the present invention and the present invention should not be interpreted as being limited to these specific examples, and the scope of the present invention shall be limited only by the appended claims.

This application corresponds to Japanese Patent Application No. 2021-046460 filed on Mar. 19, 2021 with the Japan Patent Office, and the entire disclosure of this application is incorporated herein by reference.

### REFERENCE SIGNS LIST

1: Substrate processing apparatus
1P: Substrate processing apparatus
1Q: Substrate processing apparatus
3: Controller
5: Spin chuck
6: Heater unit (substrate oxidizing unit)
9: Oxidant nozzle (substrate oxidizing unit)
10: Polymer-containing liquid nozzle (polymer-film forming unit)
12: Heating fluid nozzle (substrate oxidizing unit)
13: Mixed liquid nozzle (substrate oxidizing unit, polymer-film forming unit)
23: Spin motor (polymer-film forming unit)
82: Heater unit (substrate oxidizing unit)
101: Polymer film
102: To-be-processed layer (surface layer portion of major surface of substrate)
103: Oxide layer
130: Mixing pipe
165: Mixed liquid tank

1. A substrate processing method of etching a substrate, the substrate processing method comprising:
an oxide layer forming step of oxidizing a surface layer portion of a major surface of the substrate and forming an oxide layer; and
an oxide layer removing step of forming a polymer film that contains an acid polymer on the major surface of the substrate and removing the oxide layer by the acid polymer contained in the polymer film,
wherein the oxide layer forming step and the oxide layer removing step are alternately repeated.

2. The substrate processing method according to claim 1, wherein the polymer film additionally contains an alkaline component, and
the oxide layer removing step includes a removal starting step of starting removal of the oxide layer by heating the polymer film and then evaporating the alkali component from the polymer film after the polymer film is formed.

3. The substrate processing method according to claim 1, wherein the polymer film additionally contains an electroconductive polymer.

4. The substrate processing method according to claim 1, further comprising a polymer-film removing step of removing the polymer film from the major surface of the substrate after the oxide layer removing step is completed and before the oxide layer forming step subsequent to the oxide layer removing step is started.

5. The substrate processing method according to claim 1, wherein the oxide layer forming step includes a wet oxidation step of forming the oxide layer by supplying a liquid oxidant to the major surface of the substrate.

6. The substrate processing method according to claim 5, further comprising a rinsing step of supplying a rinsing liquid that washes the major surface of the substrate to the major surface of the substrate after the oxide layer forming step and before the oxide layer removing step.

7. The substrate processing method according to claim 1, further comprising a substrate holding step of allowing a spin chuck to hold the substrate,
wherein the oxide layer forming step includes a heating oxidation step of forming the oxide layer by heating the substrate held by the spin chuck, and
the oxide layer removing step includes a step of forming the polymer film on the major surface of the substrate held by the spin chuck.

8. The substrate processing method according to claim 7, further comprising a polymer-film heating step of heating the polymer film through the substrate by means of a heater while performing the oxide layer removing step,
wherein the heating oxidation step includes a step of forming the oxide layer by heating the substrate by means of the heater-ma.

9. The substrate processing method according to claim 1, wherein the oxide layer forming step includes a dry oxidation step of forming the oxide layer by at least any one among light irradiation, heating, and supply of a gaseous oxidant.

10. The substrate processing method according to claim 1, further comprising a polymer-containing liquid supplying step of supplying a polymer-containing liquid that contains at least a solvent and the acid polymer to the major surface of the substrate, wherein the oxide layer removing step includes a polymer-film forming step of forming the polymer film by evaporating at least a portion of the solvent contained in the polymer-containing liquid on the major surface of the substrate.

11. The substrate processing method according to claim 1, further comprising a mixed liquid supplying step of supplying a mixed liquid that contains at least a solvent, the acid polymer, and an oxidant to the major surface of the substrate,
wherein the oxide layer removing step includes a polymer-film forming step of forming the polymer film by evaporating at least a portion of the solvent contained in the mixed liquid on the major surface of the substrate, and
the oxide layer forming step includes a mixed liquid oxidation step of forming the oxide layer by means of the oxidant contained in the mixed liquid supplied to the major surface of the substrate.

12. The substrate processing method according to claim 11, further comprising a mixed liquid forming step of forming a mixed liquid by mixing a liquid oxidant and an acid polymer liquid that contains the acid polymer together in a pipe connected to a mixed liquid nozzle,
wherein the mixed liquid supplying step includes a nozzle supplying step of discharging the mixed liquid from the mixed liquid nozzle and supplying the mixed liquid discharged from the mixed liquid nozzle to the substrate.

13. The substrate processing method according to claim 11, further comprising a mixed liquid forming step of forming a mixed liquid by mixing a liquid oxidant and an acid polymer liquid together in a mixed liquid tank that supplies the mixed liquid to a pipe that guides the mixed liquid to a mixed liquid nozzle,
wherein the mixed liquid supplying step includes a nozzle supplying step of discharging the mixed liquid from the mixed liquid nozzle and supplying the mixed liquid discharged from the mixed liquid nozzle to the substrate.

14. A substrate processing apparatus that etches a substrate, the substrate processing apparatus comprising:
a substrate oxidizer that oxidizes a surface layer portion of a major surface of the substrate;
a polymer-film former that forms a polymer film containing an acid polymer on the major surface of the substrate; and
a controller that controls the substrate oxidizer and the polymer-film former so that oxidization of the surface layer portion of the major surface of the substrate by means of the substrate oxidizer and formation of the polymer film by means of the polymer-film former are alternately repeated.
